(19) United States
(12) Patent Application Publication
(10) Pub. No.: US 2025/0217312 A1
(43) Pub. Date: Jul. 3, 2025

(54) CMOS COMPATIBLE MATRIX COMPUTING NETWORK

(71) Applicant: Intel Corporation, Santa Clara, CA (US)

(72) Inventors: Zhen Zhou, Chandler, AZ (US); Ritesh Bhat, Portand, OR (US); Richard Dorrance, Beaverton, OR (US); Shailendra Sinha, Fremont, CA (US); Hechen Wang, Hillsboro, OR (US); Shuhei Yamada, Vancouver, WA (US); Tae Young Yang, Portland, OR (US)

(21) Appl. No.: 19/086,424

(22) Filed: Mar. 21, 2025

(51) Int. Cl. G06F 15/80; H03H 7/20; H03H 7/46

(52) U.S. Cl. CPC G06F 15/80; H03H 7/20; H03H 7/46

(57) ABSTRACT

Techniques are disclosed for implementing a CMOS-compatible millimeter wave matrix computing network architecture, which enables high-speed matrix operations for deep learning neural networks through a reconfigurable feedforward architecture using matrix computing meshes. Each mesh may include hybrid couplers and adjustable phase shifters. The architecture may be configured in various arrangements with programmable weights. The architecture offers advantages over existing solutions through full CMOS compatibility, the elimination of optical-electrical conversion, improved scalability, total latency, and superior power efficiency. Applications include massive MIMO systems and cognitive radar, in which the network may be implemented as part of RF front ends to reduce ADC requirements, system complexity, and power consumption.

### BACKGROUND

Matrix computing has become increasingly important for artificial intelligence and deep learning applications. Traditional matrix computing architectures utilize multiply-accumulate (MAC) operations as the primary computational method for AI processing. While MAC operations serve general AI applications, specialized matrix computing architectures have emerged to handle the intensive matrix calculations required by deep learning neural networks.

Recent developments in matrix computing hardware have explored various implementation approaches. For example, tensor processing units (TPUs) have been developed specifically for matrix-based processing, and utilize integer-based computations to improve power efficiency. Additionally, photonic implementations have investigated the use of optical components for matrix operations, though these face challenges with CMOS process compatibility and thermal management, including susceptibility to thermal crosstalk. Thus, conventional techniques and architectures for performing matrix computations have been inadequate.

### BRIEF DESCRIPTION OF THE DRAWINGS/FIGURES

The accompanying drawings, which are incorporated herein and form a part of the specification, illustrate the aspects of the present disclosure and, together with the description, and further serve to explain the principles of the aspects and to enable a person skilled in the pertinent art to make and use the aspects.

FIG. 1 illustrates a block diagram of a matrix computing network architecture, in accordance with the disclosure;

FIGS. 2A-2B illustrates a first configuration of a feed forward neural network, in accordance with the disclosure;

FIG. 2C illustrates a 3×3 subnet of the feed forward neural network as shown in FIGS. 2A-2B, in accordance with the disclosure;

FIGS. 3A-3B illustrates a second configuration of a feed forward neural network, in accordance with the disclosure;

FIG. 3C illustrates a generic representation of 8×8 network;

FIG. 3D illustrates an 8×8 mm-wave FNN, in accordance with the disclosure;

FIG. 3E illustrates a 2 layer mm-wave FNN, in accordance with the disclosure;

FIG. 3F illustrates a 3 layer mm-wave FNN, in accordance with the disclosure;

FIG. 4 illustrates a schematic diagram of a lumped element hybrid coupler used in accordance with a matrix computing network architecture, in accordance with the disclosure;

FIG. 5 illustrates a schematic diagram of a matrix computing mesh used in accordance with a matrix computing network architecture, in accordance with the disclosure;

FIG. 6 illustrates a signal flow diagram with respect to a hybrid coupler used in accordance with a matrix computing network architecture, in accordance with the disclosure;

FIG. 7 illustrates a schematic diagram of an input control block used in accordance with a matrix computing network architecture, in accordance with the disclosure;

FIG. 8 illustrates a schematic diagram of an envelope detector used in accordance with a matrix computing network architecture, in accordance with the disclosure;

FIGS. 9A-9B illustrate process flows, in accordance with the disclosure;

FIG. 10 illustrates a communication device, in accordance with the disclosure;

FIG. 11A illustrates a first type of conventional communication device;

FIG. 11B illustrates a first type of communication device implementing a matrix computing network architecture, in accordance with the disclosure;

FIG. 12A illustrates a second type of conventional communication device;

FIG. 12B illustrates a second type of communication device implementing a matrix computing network architecture, in accordance with the disclosure;

FIGS. 13A-13H illustrate weight control simulation results for various ports of a simulated 8×8 mm-wave FNN, in accordance with the disclosure;

FIGS. 14A-14D illustrate additional weight control simulation results for various ports of a simulated 8×8 mm-wave FNN, in accordance with the disclosure;

FIG. 15A illustrates an 8×8 mm-wave FNN computing speed simulation configuration, in accordance with the disclosure;

FIG. 15B illustrates an input waveform for the 8×8 mm-wave FNN computing speed simulation configuration as shown in FIG. 15A, in accordance with the disclosure;

FIGS. 16A-16B illustrate output signals for a simulated 8×8 mm-wave FNN with two different phase shifter configurations, in accordance with the disclosure;

FIG. 17A illustrates a model and simulation setup for a CMOS compatible lumped element hybrid coupler, in accordance with the disclosure; and

FIG. 17B illustrates the performance of the model CMOS compatible lumped element hybrid coupler as shown in FIG. 17A, in accordance with the disclosure.

The exemplary aspects of the present disclosure will be described with reference to the accompanying drawings. The drawing in which an element first appears is typically indicated by the leftmost digit(s) in the corresponding reference number.

### DETAILED DESCRIPTION

In the following description, numerous specific details are set forth in order to provide a thorough understanding of the aspects of the present disclosure. However, it will be apparent to those skilled in the art that the aspects, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

This disclosure generally relates to a matrix computing architecture and, in particular, to a complementary metal oxide semiconductor (CMOS)-compatible millimeter wave matrix computing network that can be configured as a feedforward neural network for performing matrix computations, such as ultra-high-speed matrix computations.

As noted above, various computing architectures, such as photonic computing, are being increasingly implemented for AI hardware development due to its low latency and high throughput features. However, photonic computing presents several challenges. First, photonic devices are not fully compatible with CMOS fabrication processes, and thus their fabrication cost is significantly higher. Second, photonic computing devices require significant overhead to perform optical-to-electrical signal conversion.

Thus, photonic computing devices may suffer from thermal control issues, as noted above. The matrix computing architecture as discussed in further detail in this disclosure addresses such issues, and may be implemented as a feed forward neural network (FNN) mm-wave network solution that provides similar latency and throughput compared to photonic computing architectures, but at a much lower cost and without the thermal issues. Additionally, because of its compatibility with CMOS technology, the matrix computing architecture as discussed herein may achieve higher computation efficiency.

To this end, it is noted that mm-wave technology represents another approach for implementing matrix computations. As used herein, the term “mm-wave” with respect to particular frequencies or frequency bands may comprise any suitable frequency or range of frequencies that are generally at least 20 GHz. For instance, mm-wave frequencies may comprise frequencies of at least 20 GHz, frequencies of at least 30 GHz, frequencies of at least 60 GHz, frequencies between 50-70 GHz, frequencies between 110-170 GHz (D band), or any suitable higher frequencies and/or frequency ranges that may be identified as or otherwise understood to be within a set of the electromagnetic spectrum associated with mm-wave frequencies.

Additionally, mm-wave frequencies and frequency bands may include those above 20 GHZ, 24 GHz, 28 GHz, etc., up to an upper frequency. For instance, mm wave frequency bands may include frequencies ranging from 20 GHz to 300 GHz, from 24 GHz to 300 GHz, etc. This may include, for instance, the various bands known to be associated with or otherwise referred to as mm-Wave frequency bands such as 24 GHz, 28 GHZ, 37 GHz, 39 GHz, 40 GHz, 47 GHZ, 60 GHz, etc. Moreover, these bands are provided as non-limiting and illustrative, and the matrix computing architecture as described herein may encompass any suitable range of frequencies outside of the mm wave frequency bands. The aforementioned mm-wave frequency bands may include additional, fewer, or alternate frequency bands than the examples described.

In any event, by operating within these mm-wave frequency ranges, the matrix computing architecture as discussed in further detail herein may advantageously leverage standard CMOS manufacturing processes while enabling high-bandwidth operation. As is discussed in further detail below, the matrix computing architecture, which may alternatively be referred to herein as an FNN architecture, may implement components that may be realized via CMOS fabrication processes, such as hybrid couplers, phase shifters, and other passive components that may be implemented using either distributed or lumped element approaches. The fundamental operation of the FNN architecture relies on the interaction of electromagnetic waves through passive networks to perform mathematical operations. By properly controlling the various relationships between signals (such as amplitude and phase), matrix operations may be implemented directly in the millimeter wave domain without requiring conversion to a different frequency band or to the digital domain.

The FNN architecture as discussed herein may include CMOS-compatible hybrid couplers and phase shifters to be arranged in matrix computing meshes, thus enabling high-speed matrix operations with low power consumption. The FNN architecture may therefore be implemented using lumped element components by leveraging CMOS fabrication technology to achieve a compact size while maintaining high bandwidth operation in the millimeter wave frequency range. In this way, the disclosed FNN architecture enables direct matrix operations in the millimeter wave domain while maintaining CMOS process compatibility and high bandwidth operation.

The FNN architecture may be implemented for deep learning applications. In accordance with such applications, a training system may be implemented that utilizes pulse-modulated RF carrier signals operating at millimeter wave frequencies to drive multi-layer matrix computing networks formed by matrix computing meshes. These meshes may achieve matrix computing speeds exceeding 0.75 TOP/see at a power consumption of 5-5.7 fJ per FLOP. The FNN architecture may thus offer significant advantages over photonic computing solutions including lower cost, a simplified design without the need for optical-electrical conversion requirements, better reconfigurability and scalability through mature assembly technology, and improved power efficiency. The FNN architecture may be configured in various arrangements, such as 4×5, 8×6, 8×8 networks, etc., with the ability to control their weights through phase shifter programming.

### I. A Matrix Computing Architecture

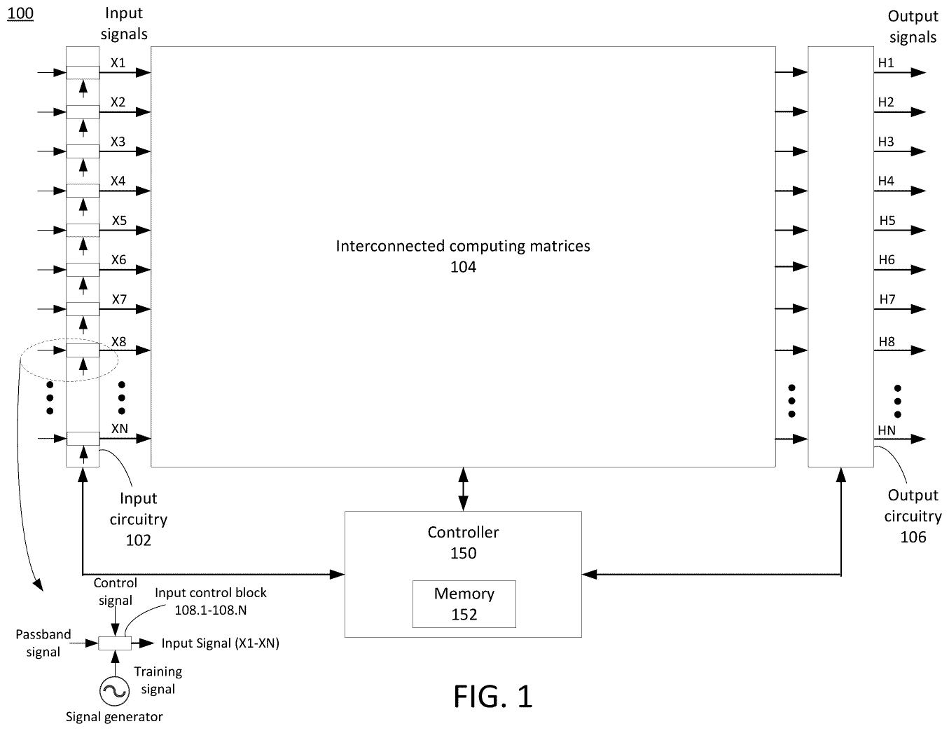

FIG. 1 illustrates a block diagram of a matrix computing network architecture, in accordance with the disclosure. The matrix computing network architecture as shown in FIG. 1 may be implemented using any suitable number and/or type of components to support any suitable type of matrix computing network. In accordance with the various non-limiting and illustrative implementations as discussed in further detail herein, the matrix computing network architecture 100 may comprise a feedforward neural network (FNN) architecture that is configured to operate in accordance with any suitable frequency or range of frequencies, such as the mm-wave frequency ranges as discussed herein.

The matrix computing network architecture 100 as shown in FIG. 1 may include input circuitry 102, interconnected computing matrices 104, output circuitry 106, and a controller 150. Each of these components may be formed as part of the same or separate devices, circuitries, chips, systems, etc. For instance, the various components of the matrix computing network architecture 100 may form part of the same system on a chip (SoC), as separate SoCs or other components that form part of the same device. Alternatively, some components of the matrix computing network architecture 100 may be part of the same device, whereas other components may be external or separate devices.

As one non-limiting and illustrative scenario, some components of the input circuitry 102 used to generate and/or control the use of the training signals may be part of a device that is separate from the other components of the matrix computing network architecture 100. However, it may be particularly useful to incorporate all components of the matrix computing network architecture 100 as part of a common device so the training process may continue to be performed by the relevant device in which the matrix computing network architecture 100 is implemented after its initial deployment, as further discussed herein. In any event, and as further discussed herein, any of the components of the matrix computing network architecture 100 may be implemented as part of a CMOS integrated circuit (IC) or other architecture that may be formed via any suitable CMOS compatible fabrication processes, which allows for reduced cost and complexity compared to photonic computing systems, as noted above. CMOS fabrication may include any suitable process that implements any suitable number and/or type of processes understood to be part of known CMOS manufacturing processes, and as such may implement one or more substrates, layers, oxidation, coatings, masking, etching, deposition, etc.

The controller 150 may comprise any suitable type of processing circuitry and may include a memory 152. The controller 150 may be configured as any suitable number and/or type of computer processors, and which may function to control the function and operation of any of the components of the matrix computing network architecture 100 as discussed herein. The controller 150 may be identified with one or more processors (or suitable portions thereof) implemented by a suitable computing device of which the matrix computing network architecture 100 is implemented. The controller 150 may be identified with one or more processors such as a host processor, a microcontroller, a digital signal processor, one or more microprocessors, a central processing unit (CPU), graphics processors such as a graphics processing unit (GPU), baseband processors, microcontrollers, an application-specific integrated circuit (ASIC), part (or the entirety of) a field-programmable gate array (FPGA), part of (or the entirety of) a system on a chip (SoC), etc.

The controller 150 may be configured to carry out instructions to perform arithmetical, logical, and/or input/output (I/O) operations, and/or to control the operation of one or more components of matrix computing network architecture 100 to perform any of the various functions as described herein. The controller 150 may include one or more microprocessor cores, memory registers, buffers, clocks, etc., and may generate electronic control signals (such as digital control signals) to control and/or modify the operation of any components of the matrix computing network architecture 100.

The memory 152 may comprise any suitable type of memory that may form part of the controller 150 and/or the matrix computing network architecture 100. The memory may store computer-readable instructions that, when executed by the controller 105, enable the controller to control the various aspects of the matrix computing network architecture 100 as discussed herein. Additionally or alternatively, the memory 152 may store training data the controller 150 may reference for the control of any components of the matrix computing network architecture 100, and thus the memory 152 may be of any suitable size and store data in any suitable data structure for these purposes.

The input circuitry 102 may be configured to receive any suitable number of “initial” input signals, which are then provided to the interconnected computing matrices 104 as the input signals X1-XN, as shown in FIG. 1. The matrix computing network architecture 100 may support any suitable number of input signals and output signals, with N representing any suitable integer value. Although the index ‘N’ is used for both the input and output signals, it will be understood that the number of signals in each case may be the same or differ from one another. In other words, the matrix computing network architecture 100 may have the same a number of inputs equal to the number of outputs or the number of inputs and outputs may be different than one another. For ease of explanation, the various implementations of the matrix computing network architecture 100 are described herein with a maximum of 8 inputs and 8 outputs with respect to the interconnected computing matrices 104, but again this is a non-limiting and illustrative scenario.

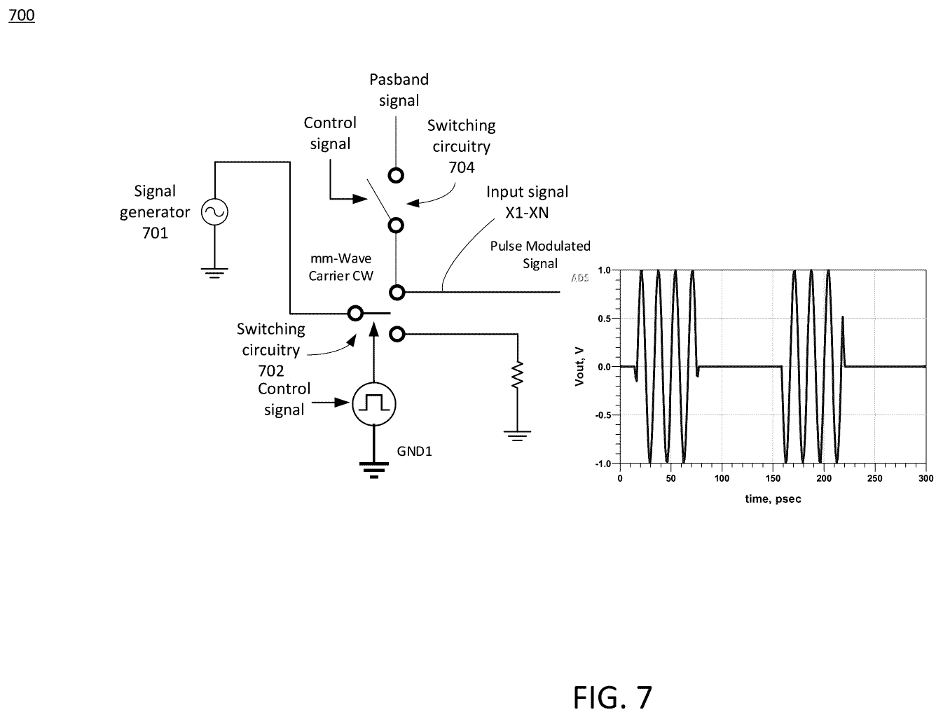

The input circuitry 102 may include any suitable number of individually controllable input control blocks 108.1-108.N, with each input control block 108 being coupled to a respective input of the interconnected computing matrices 104. For instance, each input control block may include any suitable configuration of signal switching components to enable each “initial” input signal to be provided to a respective input of the interconnected computing matrices 104 as the input signals X1-XN. Thus, these “initial” input signals may comprise what is referred to herein as passband signals, training signals, or no signal (such as by coupling a particular of the interconnected computing matrices 104 to a predetermined reference voltage such as ground). The passband signals may be alternatively referred to herein as wireless signals or communication signals, and are further discussed below. The controller 150 may control or cause other components to independently control each of the input control blocks 108.1-108.N via the generation of control signals such that each input control block 108 selectively generates, as a respective input signal X1-XN, a passband signal, a training signal, or no signal, as further discussed herein. A non-limiting and illustrative implementation of such an input control block 108 is shown in FIG. 7 and further discussed below.

Again, the input circuitry 102 is configured to selectively couple either a passband signal, a training signal, or no signal, to each respectively coupled input of the interconnected computing matrices 104 as an input signal X1-XN. The type of signal that is coupled to the inputs of the interconnected computing matrices 104 in this manner is a function of the current operational phase of the matrix computing network architecture 100. For instance, during an operating mode (also referred to herein as an operating or operational phase) occurring after a training mode (also referred to herein as a training phase) has been completed, the input circuitry 102 may receive passband signals and pass these signals on to the interconnected computing matrices 104 as the input signals X1-XN. The input circuitry 102 may thus include any suitable number, type, and configuration of components to facilitate receiving, coupling, and optionally conditioning the passband signals to provide the input signals X1-XN in this manner. This conditioning process may include amplifying, filtering, etc., of the received signals in this manner via any suitable arrangement of terminals, pins, antenna couplings, transmission line couplings, etc. In this way, the training phase may ruction to train the matrix computing network architecture 100, which may then operate during the operational phase at inference to provide the output signals H1-HN, which are inferred from the input signals X1-XN.

The passband signals received in this manner may have any suitable number of signal parameters, such as frequency, amplitude, and/or phase, and be identified with any suitable type of signal, such as complex signals or single carrier wave signals. To provide some non-limiting and illustrative scenarios, complex passband signals may be represented mathematically using complex numbers, with the real part representing the in-phase component (amplitude at a certain phase) and the imaginary part representing the quadrature component (amplitude at a 90-degree phase shift. This may include, for instance, QAM modulated signals. To provide additional non-limiting and illustrative scenarios, a single carrier wave signal may comprise a signal with amplitude and/or frequency variations, which lack the detailed phase information provided by a complex signal. The passband signals may thus may any suitable representation depending upon the periocular application, the modulation and/or coding scheme, etc. Thus, the passband signals may be received in accordance with any suitable communication protocol and/or may have any suitable carrier frequency, such as one within the mm-wave frequency range as discussed herein. In any event, the input circuitry 102 is configured, during the operating mode, to couple the wirelessly received signals to the interconnected computing matrices 104 as the inputs X1-XN, as further discussed herein, which yields the output signals H1-HN via the output circuitry 106.

Although the passbands signals are primarily discussed herein in terms of wirelessly received signals, this is a non-limiting and illustrative scenario, and the passband signals may represent any suitable type of analog signals that are coupled to the interconnected computing matrices 104 as the inputs X1-XN during the operating mode. Thus, in other scenarios, the passband signals may comprise sensor signals or other suitable analog signals that may be received from any suitable source. In any event, the input signals received in this manner may constitute analog signals received directly or indirectly from sensors or antennas, which may include the receipt of such signals without digitization or aid from any data converters.

Again, and as shown in FIG. 1, the interconnected computing matrices 104 are configured to couple the input circuitry 102 and the output circuitry 106 to one another, and thus couple the input signals X1-XN to the output signals H1-HN. In this way, the matrix computing network architecture 100 functions as a type of FNN that generates a specific set of output signals H1-HN as a function of the different combinations of input signals received at its inputs, which again are provided via the input circuitry 102. That is, the interconnected computing matrices 104 function to generate the output signals H1-HN, which have predetermined output parameters (such as amplitude and/or phase) based upon predetermined combinations of the one or more input signals received via the input circuitry 102 (and optionally other input signal parameters such as amplitude, phase, etc.). The output signals H1-HN generated in this manner may also have any suitable frequency, such one within the mm-wave frequency ranges as discussed herein. Thus, the interconnected computing matrices 104 may likewise operate in the mm-wave domain without the need for down-conversion of the input signals.

To do so, it is first noted that the matrix computing network architecture 100 may be implemented in accordance with any suitable type of application, as further discussed herein. Thus, the controller 150 may operate the matrix computing network architecture 100 during a training phase, during which different combinations of the input signals are applied to the inputs of the interconnected computing matrices 104 as training signals. The training signals may be generated to simulate the particular type of passband signals and/or signal parameters thereof that the interconnected computing matrices 104 is expected to receive during the operating mode. The training mode may thus include the controller 150 controlling each input control block 108 (via the generation of control signals) to output each respective training signal at specific times, which may have any suitable signal parameters, or output no signal.

To generate the training signals, the input circuitry 102 may comprise one or more signal generators. Thus, as one illustrative and non-limiting scenario, each training signal may comprise a generated signal having a predetermined signal parameter, which may be constant for each input of the interconnected computing matrices 104 or be varied across the inputs. Thus, as part of a training phase, these signal generators may be configured to generate respective training signals, which are selectively coupled to a respective one of the input signals of the input circuitry 102 to form different input signal combinations as the input signals X1-XN. As a non-limiting and illustrative scenario, when the predetermined signal parameter is a frequency, the signal generators may comprise carrier frequency signal generators such that the output of each signal generator is a signal having a single, predetermined frequency. The input control block 108 thus facilitates the selective coupling of the training signals in this way such that, for each one of a set of different time periods, any combination of the inputs X1-XN may be provided to the interconnected computing matrices 104.

To provide an illustrative and non-limiting scenario, for one time period during the training phase, the input control block 108 may couple all training signals to each of the inputs X1-X8 of the interconnected computing matrices 104. Then, for a subsequent time period during the training phase, the input control block 108 may couple a subset of the training signals to a corresponding subset of the inputs X1-X8 of the interconnected computing matrices 104. Then, for another subsequent time period during the training phase, the input control block 108 may couple yet another, different subset of the training signals to a corresponding different subset of the inputs X1-X8 of the interconnected computing matrices 104, and so on.

As further discussed below, during each of these time periods, the controller 150 may also measure one or more predetermined signal parameters of the output signals H1-H8 as a function of the varying weights applied to the interconnected computing matrices 104. Thus, during the training phase, the controller 150 may generate a set of correlations over time between input signal combinations, any input signal parameters, weights, and predetermined signal parameters of the output signals H1-H8. In this way, the training data may contain a mapping of all (or a significant number) of anticipated input signal combinations of passband signals, which may be accessed during operation to output the desired predetermined signal parameters of the output signals H1-H8 for the same input signal combinations used during training.

Thus, the training signal may be generated having a frequency that corresponds to that of the passband signals expected to be received during the operating mode, as noted above. However, as each input control block 108.1-108.N may be individually controlled, the training signals may be generated such that different combinations of the training signals are provided to the different inputs of the interconnected computing matrices 104 at different times. Again, this may include providing each training signal with the same amplitude or different amplitudes as discussed above. Of course, the training phase may additionally or alternatively include adjusting different signal parameters of the training signals based upon the particular application, such as phase, frequency, etc.

Furthermore, the output circuitry 106 may include any suitable number and/or type of components to enable the controller 150 to sample any suitable signal parameters of the output signals H1-H8. This may include, for instance, envelope detectors to facilitate the measurement of an amplitude of the resulting output signals H1-H8 for a specific combination of input signals X1-X8 and their accompanying signal parameters. Thus, it is noted that based upon the particular application, the controller 150 “knows” which desired signal parameters and combination of output signals H1-HN are to be output for a specific combination of input signals X1-XN and their corresponding signal parameters.

However, the determination of how to generate these control signals as a function of the weights of the interconnected computing matrices 104 may be performed via the controller 150 leveraging training data, which may be stored in the memory 152 upon completion of the training phase. As will be discussed in further detail herein, the specific combination of output signals H1-H8 and their predetermined signal parameters may be known based upon knowledge of the underlying wireless architecture. However, the manner in which these output signals are actually generated having the desired properties conventionally requires significant processing in the digital domain. That is, the conventional control schemes used in wireless applications to provide the desired output signals for the next processing stage typically require performing a signal transformation using digital signal processing via downsampling and conversion to the digital domain, which requires significant processing power and may introduce latency.

Thus, the matrix computing network architecture 100 as discussed herein addresses these issues via the use of the training phase and its operation in the analog domain prior to down-conversion. For instance, by iteratively applying different combinations of the training signals as the input signals X1-XN, adjusting weights of the interconnected computing matrices 104, and measuring the resulting output signal parameters of the output signals H1-HN, a set of training data may be obtained and stored in the memory 152. The training data functions to map the different combinations of the input signals X1-XN and their accompanying signal parameters to a desired set of output signals H1-HN having predetermined output signal parameters. These input signal parameters and combinations may thus include labels that are typically used in accordance with the training process of various machine learning models. The mapping identified in the training data may therefore include the weights applied to the matrix computing network architecture 100 by the control signals generated via the controller 150, as further discussed herein, for various combinations of input signals, output signals, and their respective signal parameters. Then, during the operating mode, the controller 150 may access this training data to apply the desired weights to the matrix computing network architecture 100 such that the desired output signals H1-HN are generated for a specific set of wirelessly received signals coupled to the inputs of the matrix computing network architecture 104 as the input signals X1-XN.

Thus, the interconnected computing matrices 104 enable an analog and CMOS-compatible technique for providing an FNN for this purpose. To do so, the ability to perform signal parameter measurements is exploited as the signals propagate through the interconnected computing matrices 104 versus the conventional manner of computing these results. Additional details regarding the structure and operation of the interconnected computing matrices 104 is provided in further detail below.

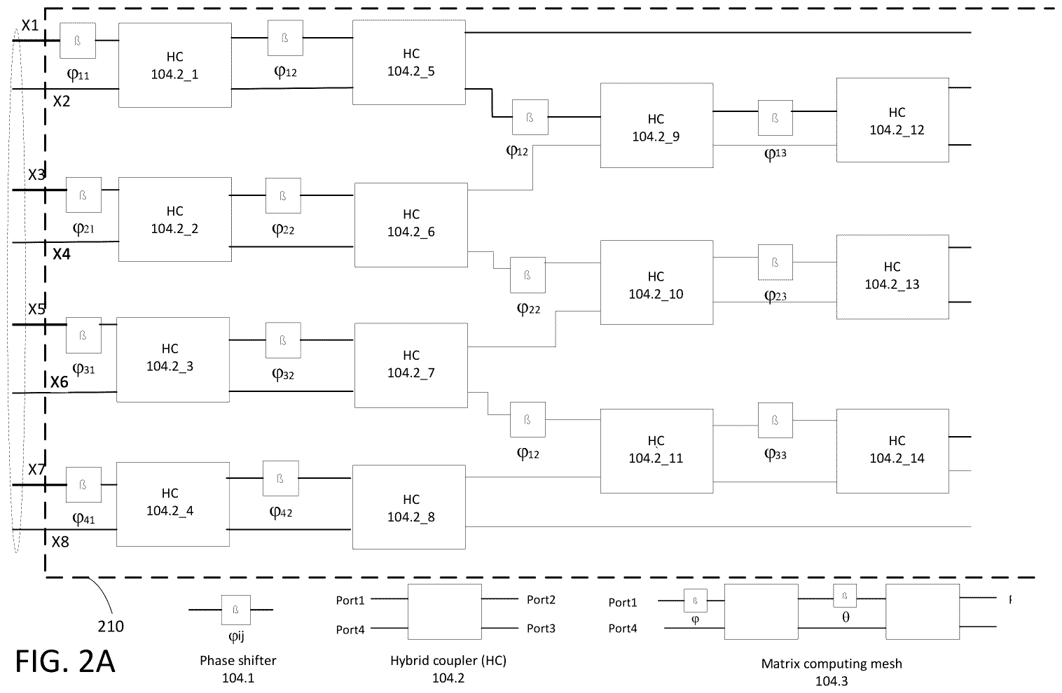

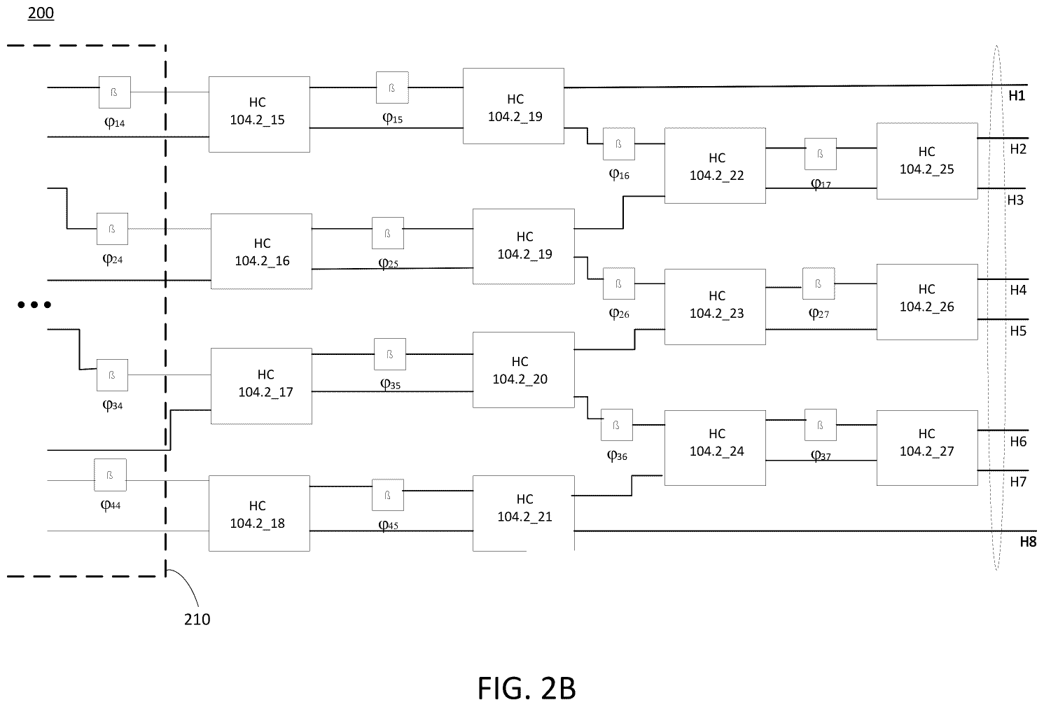

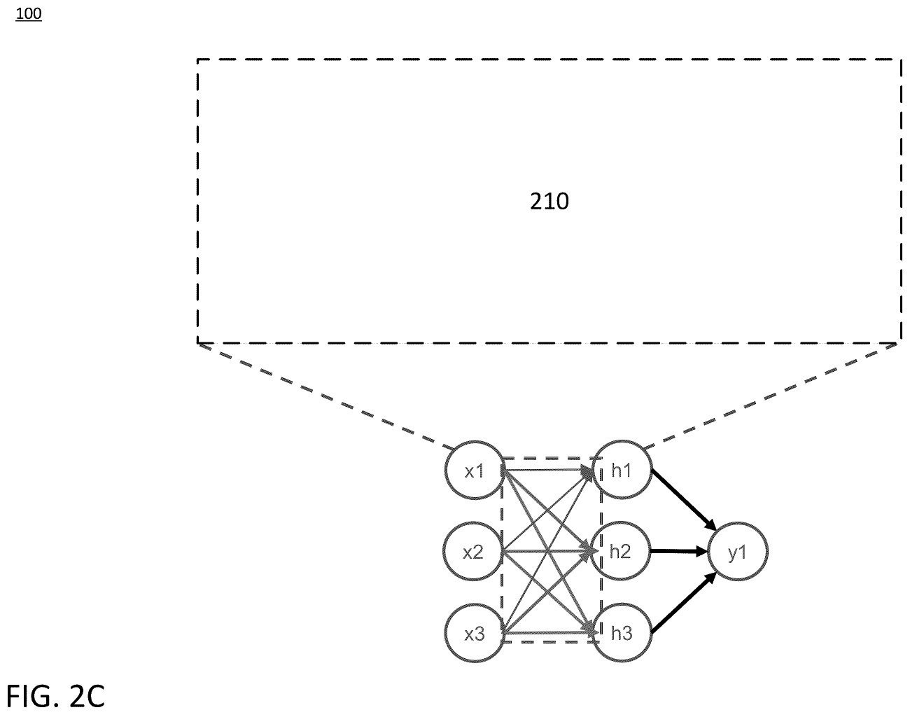

FIGS. 2A-2B illustrate a feed forward neural network (FNN), in accordance with the disclosure. The FNN 200 as shown in FIGS. 2A-2B may be identified with the interconnected computing matrices 104 as shown in FIG. 1, and may represent a reconfigurable FNN as discussed in further detail herein. FIG. 2A shows one half of the interconnected computing matrices 104, which includes the input connections to receive the input signals X1-XN, whereas FIG. 2B shows another half of the interconnected computing matrices 104, which includes the output connections to provide the output signals H1-HN. The off page ellipses note respective connections between each of these halves to form the overall interconnected computing matrices 104. It will be understood that the FNN 200 may include additional or fewer components than those shown in FIGS. 2A-2B, may include a different configuration of interconnections, and may include a different configuration of phase shifters. Additionally, the FNN 200 may include other components not shown in FIGS. 2A-2B, such as the input circuitry 102 and output circuitry 106 as shown and discussed in FIG. 1, which are not shown in FIGS. 2A and 2B for purposes of brevity.

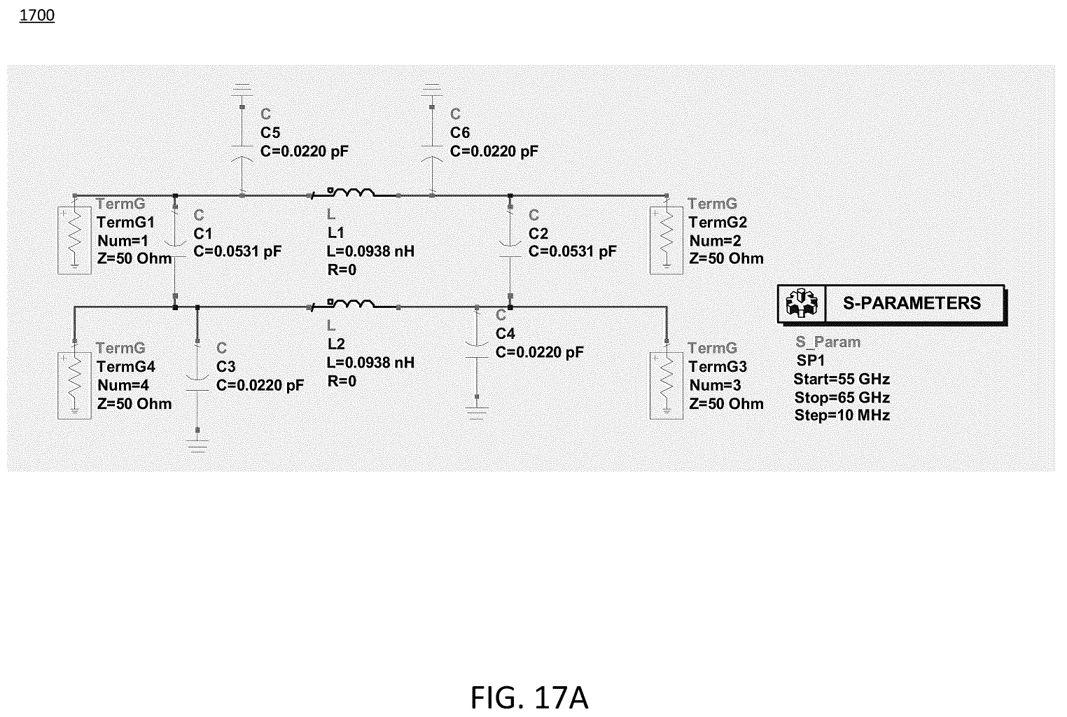

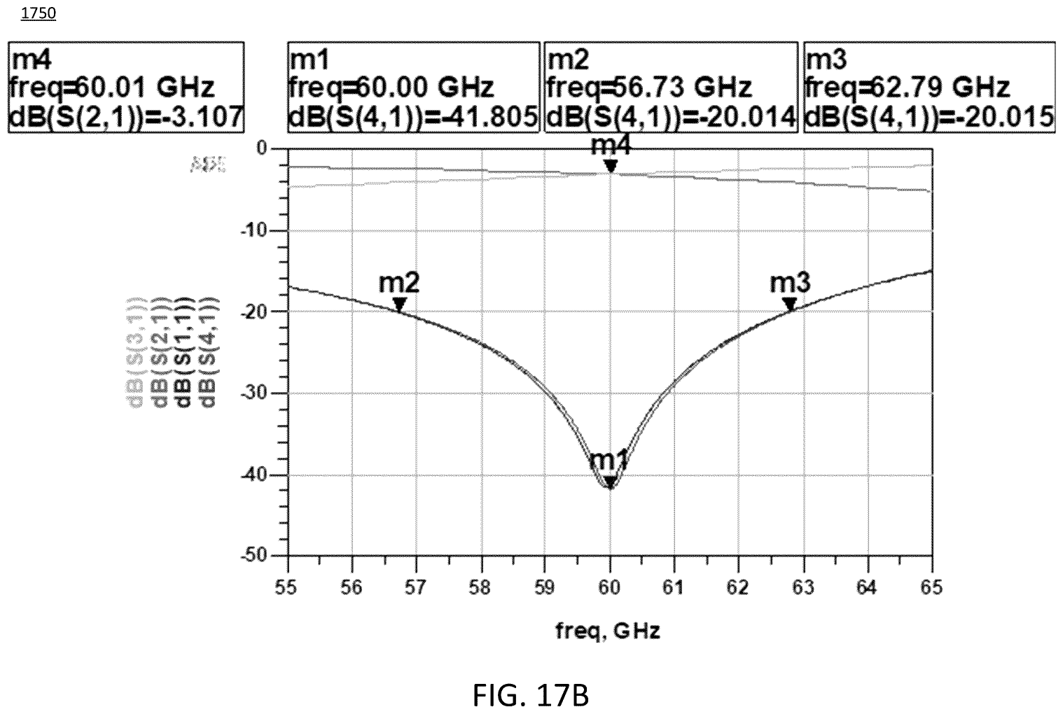

Again, the FNN 200 as shown in FIGS. 2A-2B may include the interconnected computing matrices 104. Each computing matrix of the interconnected computing matrices 104 may be alternatively referred to herein as a matrix computing mesh, such as the matrix computing mesh 104.3 as shown in FIG. 2A. The matrix computing mesh may comprise a unitary or a non-unitary computing matrix, in various non-limiting and illustrative scenarios. That is, depending on the particular implementation, the matrix computing performed when a signal passes through the matrix computing mesh 104.3 may be unitary when there is very little loss or, alternatively, non-unitary if the signal passes through the matrix computing mesh 104.3 as a lossy network. Furthermore, it is noted that for the matrix computation mesh 104.3 to support a mm-wave FNN, the hybrid coupler's 104.2 that are used for its implementation should meet a predetermined signal to noise and distortion ratio (SINDR) criterion. Thus, the hybrid coupler's 104.2 should be selected to have a suitable bandwidth, which is defined as a frequency band within which the SINDR meets this requirement. Additional details regarding such a suitable hybrid coupler meeting this criterion are discussed below with respect to FIGS. 17A-17B.

Thus, and with continued reference to FIG. 2A, each matrix computing mesh 104.3 may comprise a set of hybrid couplers (HC) 104.2 and a set of adjustable phase shifters 104.1. In the configuration as shown in FIGS. 2A-2B, each matrix computing mesh 104.3 comprises two hybrid couplers 104.2 and two adjustable phase shifters 104.1, with one of the adjustable phase shifters 104.1 being coupled to a first port (i.e. port 1) of the first (leftmost) hybrid coupler 104.2. Another of the two adjustable phase shifters 104.1 is also coupled to a second port (i.e. port 2) of first (leftmost) hybrid coupler 104.2, and is also coupled to a first port (i.e. port 1) of the hybrid coupler 104.2. However, this is a non-limiting and illustrative scenario, and each matrix computing mesh 104.3 may have a different configuration than that shown in FIGS. 2A-2B.

Again, and as shown in FIGS. 2A-2B, the interconnected computing matrices 104 may include any suitable number of hybrid couplers 104.2. As further discussed below, the hybrid couplers 104.2 may comprise any suitable type of hybrid coupler having any suitable number of ports, with four being shown, and may be configured to operate within a range of frequencies based upon the particular application, such as mm-wave frequencies as discussed herein. The hybrid couplers 104.2 may be implemented as lumped element hybrid couplers and formed as part of the same CMOS IC (or other suitable CMOS component such as a SoC, etc.) as the FNN 200. Thus, the various interconnections of the FNN 200 as shown in FIGS. 2A-2B may comprise any suitable configuration of transmission lines, which are also configured to operate within a range of frequencies based upon the particular application, such as mm-wave frequencies as discussed herein. The transmission lines, as well as all other components of the FNN 200, may likewise be formed as part of the same CMOS component. Thus, in a non-limiting and illustrative scenario, the set of interconnected computing matrices 104 may be interconnected via on-chip transmission lines, which may be formed as part of the monolithic CMOS IC that includes any suitable portion (or the entirety) of the components of the FNN 200.

Each adjustable phase shifter 104.1 is configured to be individually and independently controlled with respect to one another to provide an adjustable phase shift in response to a control signal generated by the controller 150. As will be further discussed herein, the controller 150 may thus control (such as via digital control schemes) the phase shift provided to the signals received via each of the various phase shifters 104.1 within the interconnected computing matrices 104. By controlling the phase of the phase-shifters 104.1 in each matrix computing mesh 104.3, the input to each matrix computing mesh 104.3 is appropriately weighted at its respective output.

In this way, the controller 150 may access the training data as noted above, and adjust the phase shift provided by each of the phase-shifters 104.1 within the interconnected computing matrices 104. Using the previous illustrative scenario in which the amplitude of the output signals H1-HN is to be determined based upon a specific combination of the input signals X1-XN, it is noted that the training data in this scenario may define an amplitude of the output signals H1-HN based upon predetermined combinations of the input signals. This predetermine combination of the of the input signals may include a specific subset (or all) of the input signals being actively received at the inputs of the interconnected computing matrices 104, each having the same signal parameters such as amplitude, phase, frequency, etc., or different signal parameters, as the case may be. Furthermore, the training data may correlate, for a particular predetermined combination of input signals X1-XN (such as a specific combination of passband signals expected to be received during operation), the amplitude of the output signals H1-HN to weights identified in the training data, which may comprise or otherwise be represented as a function of the phase shift values of each one of the set of adjustable phase shifters 104.1.

Again, and continuing the current scenario in which the predetermined output parameters of the output signals H1-HN comprise an amplitude, the output circuitry 106 may comprise a set of envelope detectors, each being configured to independently measure a respective amplitude of the output signals H1-HN. The controller 150 may measure an output of each of these envelope detectors during the training phase to ensure that the appropriate phase values, when applied to specific combinations of the input signals X1-XN, result in the desired amplitudes of the output signals H1-HN. Such a determination may be made, in one non-limiting and illustrative scenario, when the measured amplitude of each of the output signals H1-HN is within a predetermined threshold range of amplitudes. Additionally, during the operating mode the controller 150 may measure an output of each of these envelope detectors to determine whether the amplitude of each output signal H1-HN is within a threshold range of amplitudes. That is, the controller 150 may utilize such envelope detector measurements as feedback to determine whether to re-adjust the phase values as needed by once again determining whether the amplitude of each output signal H1-HN is within a threshold range of amplitudes. Once the output signals H1-HN have the appropriate amplitude values, the controller 150 may perform any suitable function, such as signaling a higher-level system component that the output signals H1-HN are ready for processing.

Again, the FNN 200 may include any suitable number of phase shifters 104.1 to implement this functionality, and these phase shifters 104.1 may be connected in a different arrangement than that shown in FIGS. 2A-2B. Additionally or alternatively, the FNN 200 may include other components that enable its reconfigurability, such as switches that may allow for the each of the matrix computing meshes 104.3 to be connected to one another in a different way. In this way, different configurations of the FNN may be realized using a single hardware implementation. Additionally or alternatively, the FNN 200 may include electronically-controllable switches configured to selectively couple any of the input signals X1-XN to any of the outputs of the input circuitry 102, to selectively couple any of the output signals H1-HN to any of the outputs of the output circuitry 106, etc. Alternatively, the FNN 200 may be implemented as a single, non-reconfigurable design for a particular application.

As a non-limiting and illustrative scenario, the FNN 200 may be configured as a 4×5 network by driving input X1 to X4 and taking the output signal at H1 to H5. In this case, the weight from each input to each output may be fully controlled by programing the phase shifter φᵢⱼ (i=1,2 and j=1,2,3,4,5,6,7). Similarly, the inputs may be X5 to X8 and the output signals may be H8 to H5. Alternatively, the network presented in FIGS. 2A-2B may be arranged as an 8×6 network with input signals at X3 to X6 and output signals taken at H2 to H7, with proper phase-shifter configurations to control each input-to-output weight. Additionally, for some applications, the FNN 200 may be implemented as an 8×8 network with partially controlled weights for each input at each output. In this way, the FNN 200 may be treated as a deep learning neural network (DLNN) with two hidden layers by cascading two of the 3×3 sub-nets together (shown as the subnet 210 in FIGS. 2A-2B, which is reproduced in FIG. 2C for clarity), with a representation of a single 3×3 subnet 210 being shown in FIG. 2C. Furthermore, a more complicated DLNN may be formed by networking these 3×3 subnets.

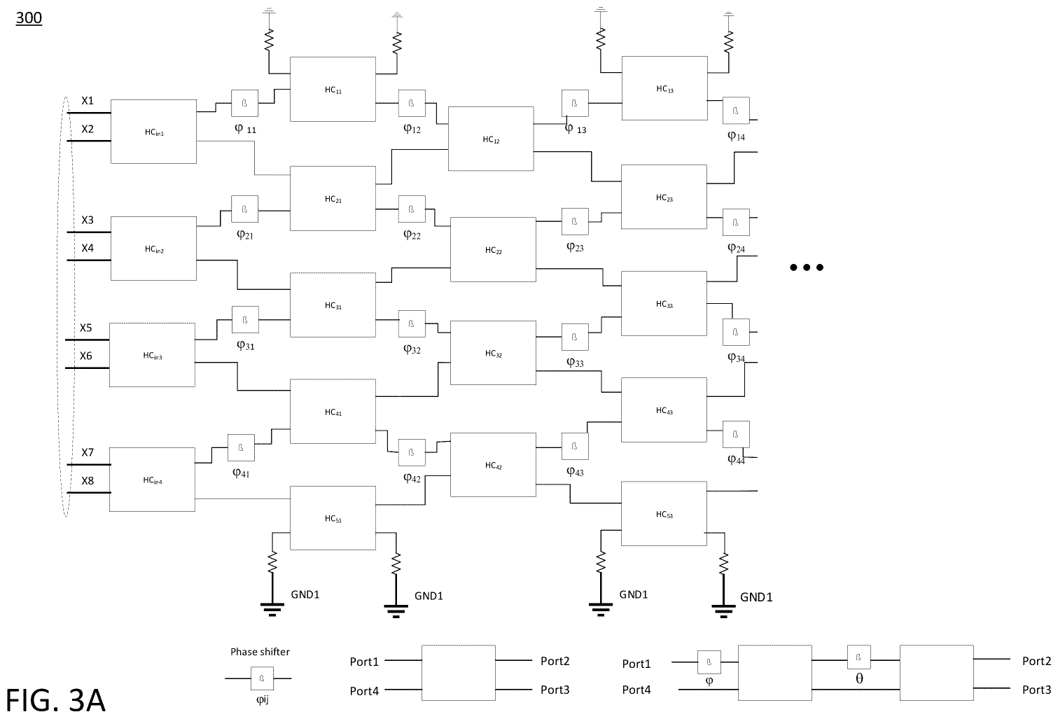

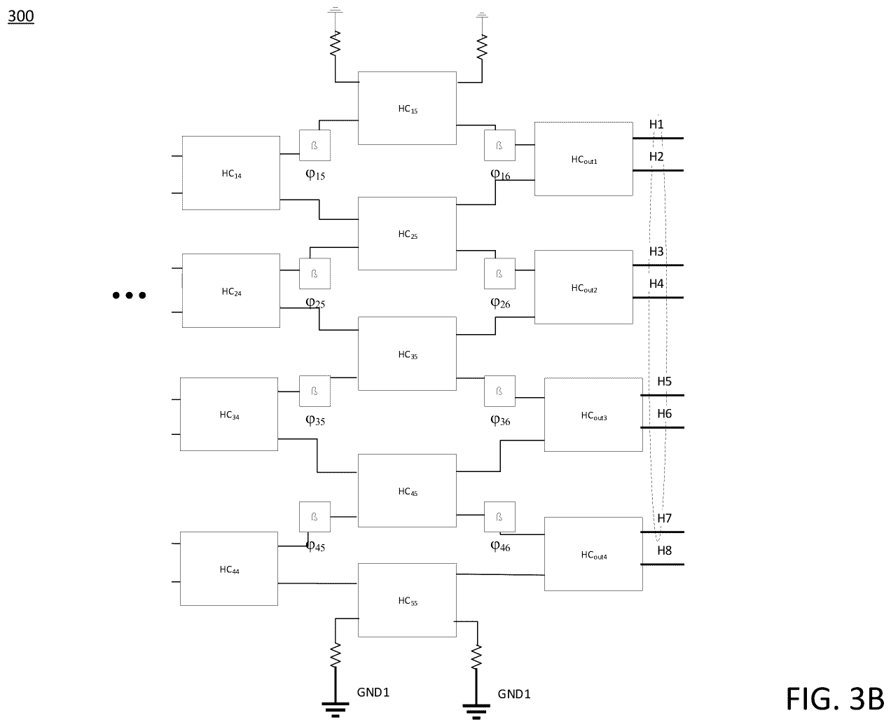

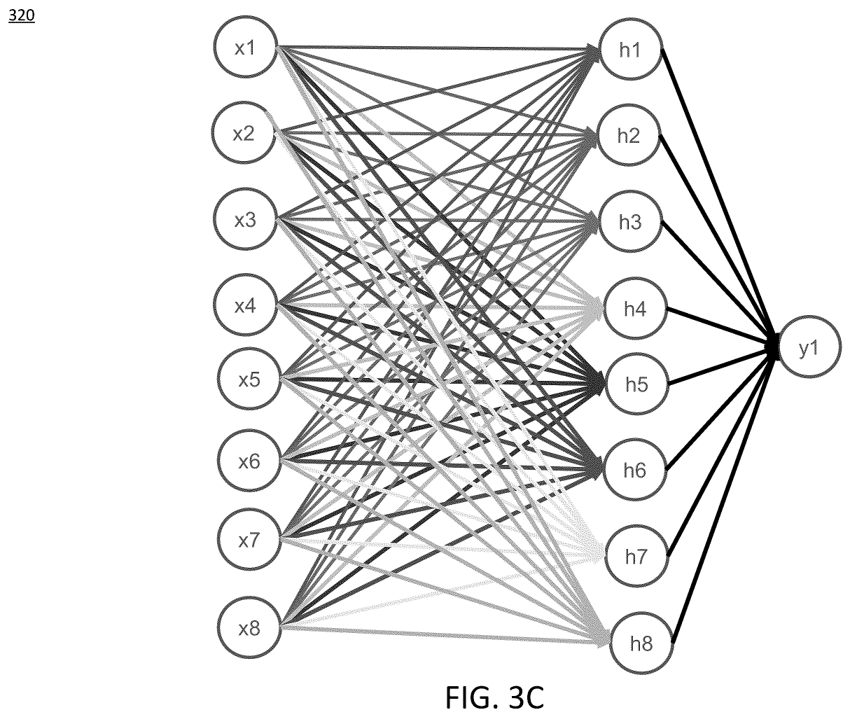

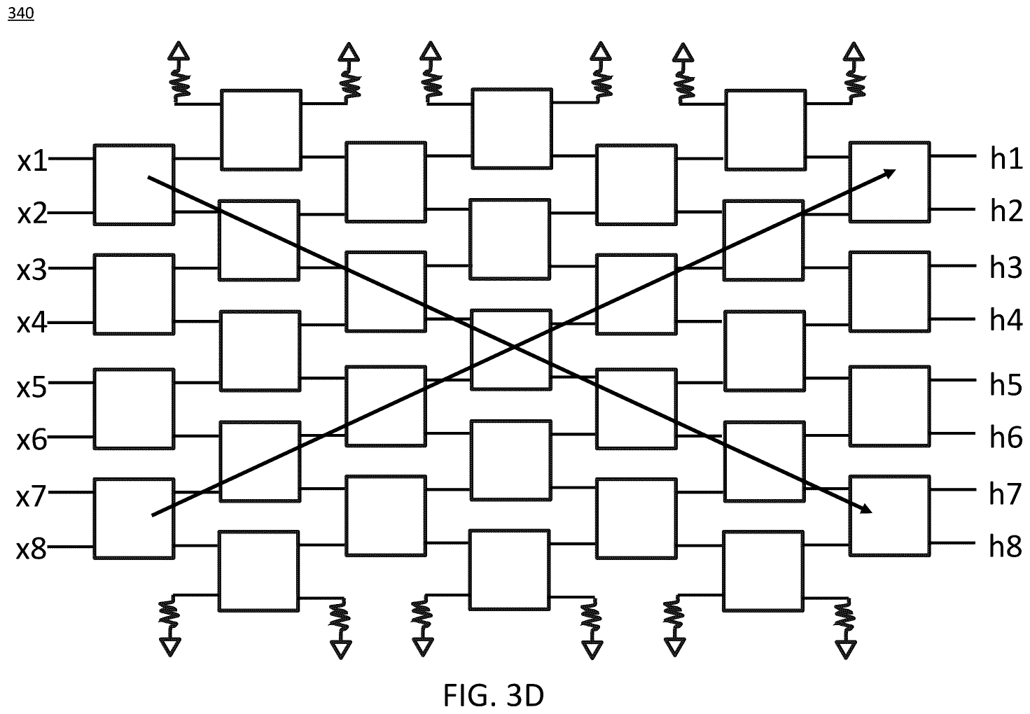

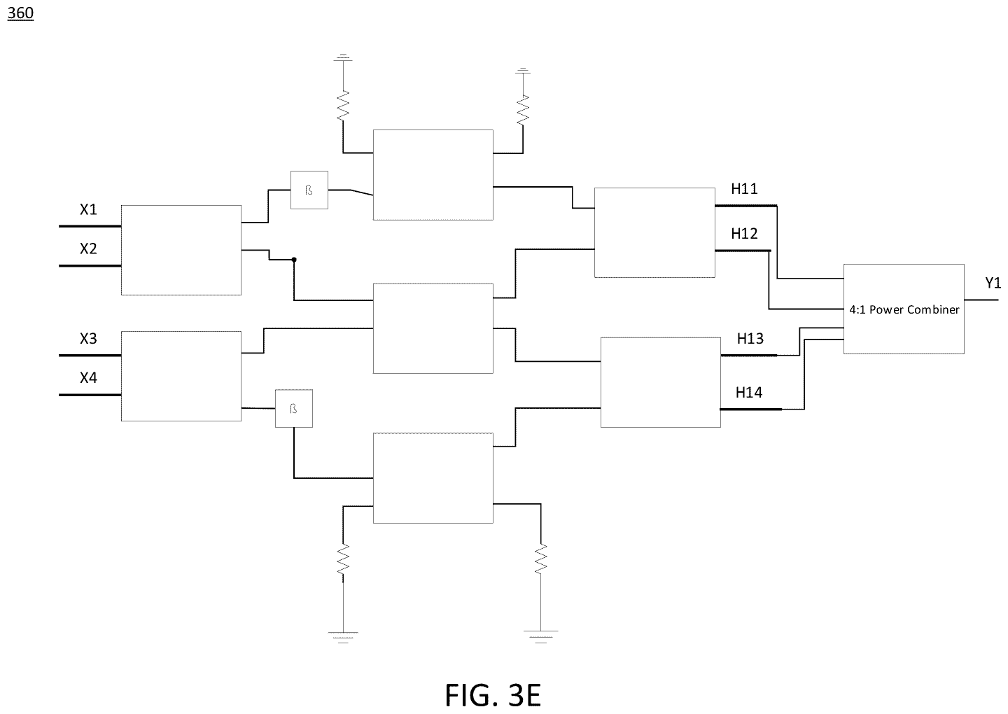

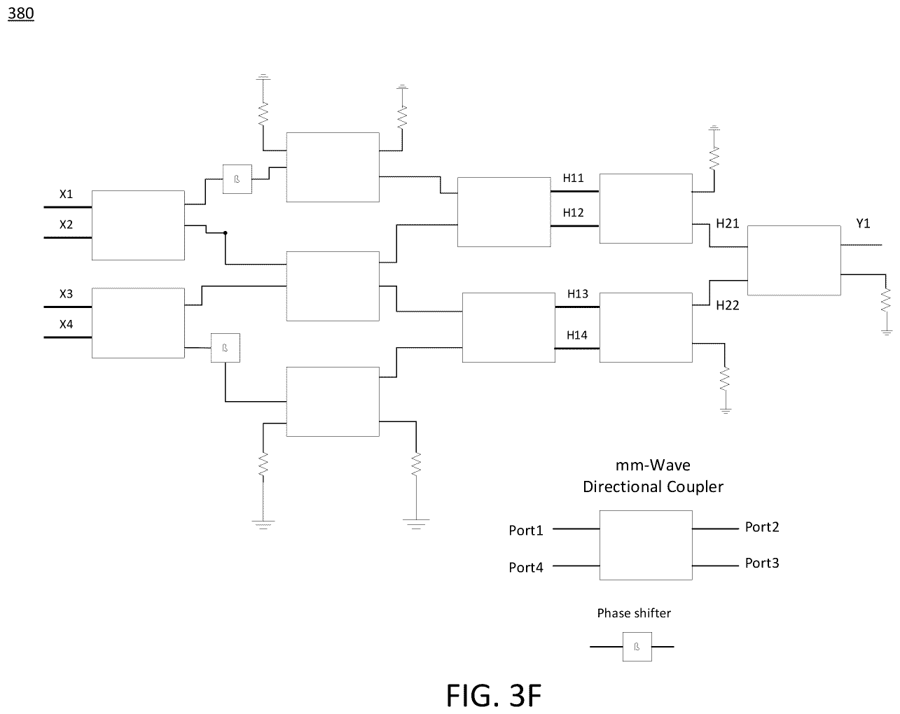

To provide another illustrative and non-limiting scenario, FIGS. 3A-3B illustrate a second configuration of a mm-wave FNN, which is illustrated in FIG. 3C as an equivalent 8×8 FNN network. Any of the statements made with respect to the FNN 200 as shown in FIGS. 2A-2B are also applicable to the FNN 300 as shown in FIGS. 3A-3B. For instance, the FNN 300 may implement the same interconnected matrix computing meshes 104.3 as explained above. Additionally, the FNN 300 may be reconfigured to realize different layered FNNs. In other words, any configuration may be realized via the weight control mechanisms as discussed herein. One non-limiting and illustrative scenario of a 2 layer mm-wave FNN is shown in FIG. 3E, whereas another non-limiting and illustrative scenario of a 3 layer mm-wave FNN is shown in FIG. 3F.

However, and referring back to FIGS. 3A-3B, different from the FNN 200, the FNN 300 implements 31 hybrid couplers and 16 phase shifters to form an interweaved FNN. As further illustrated in FIG. 3D, the utilization of the interweaving pattern of interconnected matrix computing meshes 104.3 may balance the weight controllability with a minimum number of phase shifters. Thus, the configuration of the FNN 300 as shown in FIGS. 3A-3B may advantageously provide a reduction in the power required for operating the phase shifters, as well as a reduction in the network area. Again, through the arrangement of interconnected matrix computing meshes 104.3, weights from inputs to outputs may be controlled by tuning the appropriate phase-shifters, as noted above.

Again, it is noted that via weight control, any suitable combinations of inputs to outputs may be achieved. That is, the output signals H1-H8 may be combined to provide any suitable number of combined output signals Y1-YN, with FIG. 3C illustrating the combination of all output signals H1-H8 into a single combined output signal Y1. This combined signal Y1 may optionally be amplified. This amplification may be particularly useful to perform non-linear activation before the combined signal Y1 is down-converted to a digital signal. Thus, compared to a conventional photonic DLNN, this approach does not require a down-conversion back to the digital domain for the non-linear activation, which provides a significant advantage.

The hardware components for performing the combination and optional amplification of the combined output signal are not shown in FIGS. 3A-3B for purposes of brevity and ease of explanation. However, the FNN 300 as shown in FIGS. 3A-3B may include any suitable number and/or type of components configured for this purpose, which may be formed using CMOS fabrication technology and/or part of the same CMOS IC (or other component) as the other components of the FNN 300. To provide an illustrative example, the output signals H1-H8 may be combined using any suitable type of power combiner having a number of inputs that is a function of the number of output signals H1-HN that are to be combined. A non-limiting and illustrative scenario of such a combining component is shown in FIG. 3E as a 4:1 power combiner. Furthermore, the amplification of the combined output signal may be implemented using any suitable type of amplifiers, which may include low noise amplifiers or other known amplification techniques. It is noted that such a combiner, when present, may be implemented prior to or after activation to form different networks.

Turning now back to FIGS. 2A-2B and 3A-3B, with respect to the hybrid couplers 104.2, it is noted that hybrid couplers are typically implemented as microwave devices, which play a critical role in various signal path functions such as mixing, providing variable attenuation, modulation, etc. As noted above, for the matrix computing network architectures as discussed herein, the hybrid couplers 104.2 are implemented to serve as part of respective matrix computing meshes 104.3, which may be interconnected as discussed herein to form a mm-wave FNN. Thus, the hybrid couplers 104.2 may be implemented using any suitable components and/or technology, which may include the use of CMOS technology that utilizes quarter wavelength transmission lines, lumped L-C elements, etc.

However, to have a compact size and be CMOS compatible, it may be particularly useful to implement the hybrid couplers 104.2 as a lumped element network. Thus, the hybrid couplers 104.2 may be referred to as lumped element hybrid couplers, which may include any suitable number and/or type of lumped elements. These lumped elements may comprise discrete components and/or components that are formed via traces or other portions of a CMOS substrate, CMOS traces, or other portions of a suitable of a CMOS component such as an IC.

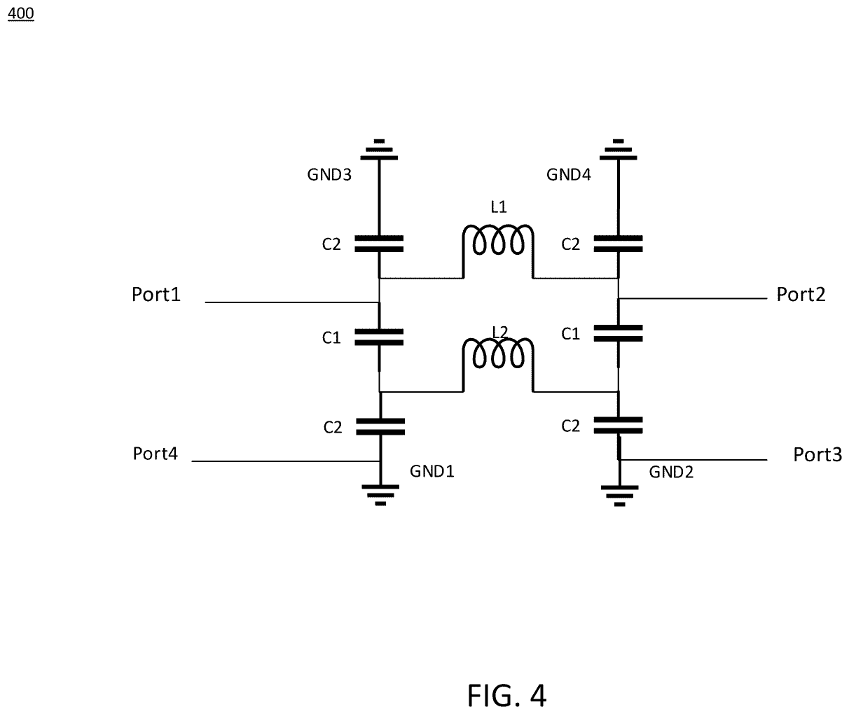

A schematic diagram of such a lumped element hybrid coupler is shown in FIG. 4, which may be identified with the hybrid couplers 104.2 in one non-limiting and illustrative scenario. The lumped-element hybrid coupler as shown in FIG. 4 comprises a 3-dB hybrid coupler, which divides the input signal received at each of the ports 1 and 4 equally into two output ports (ports 2 and 3), with a 90-degree phase shift between them. However, the use of a 3-dB hybrid coupler is a non-limiting and illustrative scenario, and the matrix computing network architectures as discussed herein may implement any suitable type of hybrid coupler as the interconnected hybrid couplers 104.2.

With continued reference to FIG. 4, the behavior of a 3-dB hybrid coupler is governed by a scattering parameter (S-parameter) matrix, which relates an incident wave to the reflected wave at each port. For a lossless and well-matched hybrid coupler, its S-parameter matrix is represented by Equation 1 below, and assumes a unitary matrix.

$$[ \begin{matrix}{V}_{1}^{-} \\ {V}_{2}^{-} \\ {V}_{3}^{-} \\ {V}_{4}^{-}\end{matrix} ] = \frac{1}{\sqrt{2}} [ \begin{matrix}0 & 1 & j & 0 \\ 1 & 0 & 0 & j \\ j & 0 & 0 & 1 \\ 0 & j & 1 & 0\end{matrix} ] [ \begin{matrix}{V}_{1}^{+} \\ {V}_{2}^{+} \\ {V}_{3}^{+} \\ {V}_{4}^{+}\end{matrix} ] \qquad Eqn . 1$$

With respect to Eqn. 1, Vⱼ⁺ represents the incident wave (input wave) at the j^{th} port, while Vⱼ⁻ is the reflected wave (output wave) at the j^{th} port. Equation 2 below is derived from Equation 1 to relate the inputs at port 1 and port 4 to the outputs at port 2 and port 3.

$$[ \begin{matrix}{V}_{2}^{-} \\ {V}_{3}^{-}\end{matrix} ] = \frac{1}{\sqrt{2}} [ \begin{matrix}1 & j \\ j & 1\end{matrix} ] [ \begin{matrix}{V}_{1}^{+} \\ {V}_{4}^{+}\end{matrix} ] \qquad Eqn . 2$$

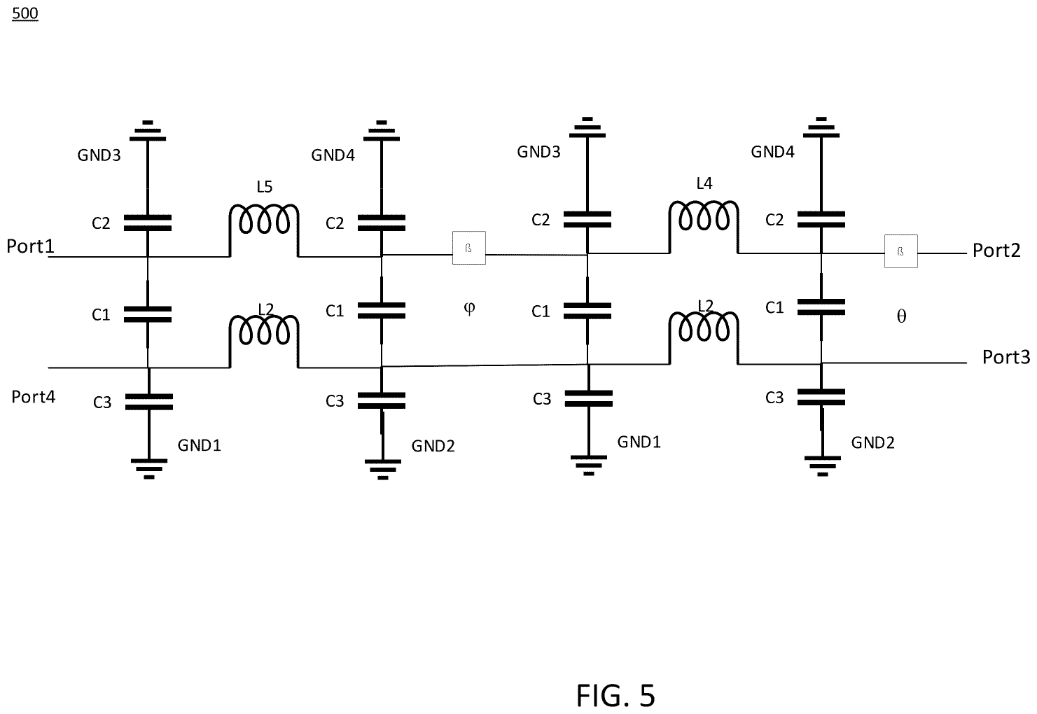

To control the weight of the matrix given by Eqn. 2, FIG. 5 illustrates a schematic diagram of a matrix computing mesh used in accordance with a computing network architecture, in accordance with the disclosure, which may be identified with the matrix computing mesh 104.3 as shown in FIG. 2A. The matrix computing mesh as shown in FIG. 5 thus represents a tandem of hybrid couplers 104.2 and phase shifters 104.1. Thus, the schematic in FIG. 5 shows the ports 2 and 3 of a hybrid coupler 104.2 being coupled to ports 1 and 2, respectively, of another hybrid coupler 104.2 to form the matrix computing mesh 104.3 as shown in FIG. 2A. The input and output relationship of ports in this combined network is represented below in Equation 3.

$$[ \begin{matrix}{V}_{2}^{-} \\ {V}_{3}^{-}\end{matrix} ] \frac{1}{2} [ \begin{matrix}1 & j \\ j & 1\end{matrix} ] [ \begin{matrix}{e}^{j φ} & 0 \\ 0 & 1\end{matrix} ] [ \begin{matrix}1 & j \\ j & 1\end{matrix} ] [ \begin{matrix}{e}^{j θ} & 0 \\ 0 & 1\end{matrix} ] [ \begin{matrix}{V}_{1}^{+} \\ {V}_{4}^{+}\end{matrix} ] [ \begin{matrix}{e}^{j θ} ( {e}^{j φ} + 1 ) & j ( {e}^{j φ} + 1 ) \\ {je}^{j θ} ( {e}^{j φ} + 1 ) & - ( {e}^{j φ} - 1 )\end{matrix} ] [ \begin{matrix}{V}_{1}^{+} \\ {V}_{4}^{+}\end{matrix} ] \qquad Eqn . 3$$

Thus, Eqn. 3 provides a relationship that may be evaluated by the controller 150 to control the phase of each phase shifter of each matrix computing mesh 104.3 to thereby control the weights of the underlying mm-wave FNN. In other words, the controller 150 may adjust the weights of the mm-wave FNN represented by the underlying computing network architecture by adjusting, for each one of the interconnected matrix computing meshes 104.3, phases of the adjustable phase shifters in each respective matrix computing meshes 104.3. And by evaluating Equation 3 above, the controller 150 may adjust the weights of the mm-wave FNN as a function of changes in S-parameters with respect to each respective set of hybrid couplers 104.2 and set of phase shifters 104.1.

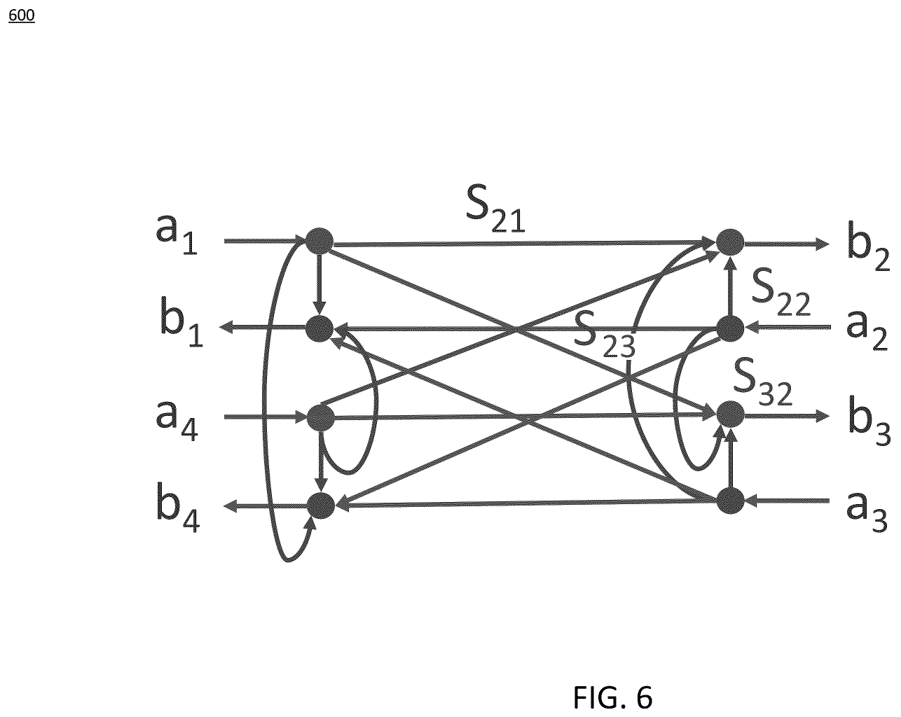

To provide further clarity, FIG. 6 illustrates a signal flow diagram with respect to a hybrid coupler, which may be identified with the hybrid coupler 104.2. For the signal flow diagram as shown in FIG. 6, each port has two nodes. Node aⱼ is the node where the wave enters the j^{th} port, while bⱼ is the node where the wave leaves the j^{th} node. Thus, when the hybrid coupler is driven at port 1 with an input of a₁, the signal output at port2 is b₂. Meanwhile, the distortions appearing at port 2 originate from two different sources: one is the reflection at port 2 designated as S₂₂, while another is the wave leakage from port 3, which can be calculated as S₃₁*S₃₂.

With this in mind, the aforementioned SINDR of the hybrid coupler may thus be defined in accordance with Equation 4 below as follows:

$$SINDR = 10 {log}_{10} \frac{{P}_{signal} + {P}_{distortion} + {P}_{noise}}{{P}_{distortion} + {P}_{noise}} = 10 {log}_{10} ( 1 + \frac{{P}_{signal}}{{P}_{reflection} + {P}_{isolation}} ) \vert ( P\_noise = 0 ) \qquad Eqn . 4$$

Thus, with reference to Eqn. 4 and considering a hybrid coupler to be a passive network with negligible noise, when the hybrid coupler is driven at the input port 1, its SINDR at the output port 2 can be calculated in accordance with Equation 5 below as follows:

$$SINDR = 10 {log}_{10} ( 1 + \frac{{S}_{21}}{( {S}_{22} + {S}_{32} )} ) \vert ( P\_noise = 0 ) \qquad Eqn . 5$$

Thus, assuming that the envelope detection via the output circuitry 106 requires 15 dB SNDR, this translates the requirement for the ratio of distortion versus transmission to be above 10 dB. Using this criterion, it is further assumed that the hybrid coupler 104.2 (implemented as a lumped element hybrid coupler) has a bandwidth of 6 GHz (from 56.7 GHz to 62.79 GHz). In this scenario, the hybrid coupler 104.2 may be implemented as part of an 8×8 mm-wave FNN, such as those shown in FIGS. 2A-2B and 3A-3B, to provide a throughput as high as 0.768 TOPs.

To demonstrate the advantages of the mm-wave DLNN-FNN matrix computing architecture as shown in FIGS. 2A-2B and 3A-3B versus a conventional PDLNN, Table 1 is provided below that compares performance metrics of each network architecture. For this comparison, an area estimation for the lumped element-based hybrid coupler is assumed to be based on a 22 nm process. The area of each capacitor is estimated to be 2˜10 um². Furthermore, assuming the inductor coil may be made of a square shape with 5 turns, the area for the inductor may be as small as 3.75×3.75 um² to provide a 0.0938 nH inductance. The total area for the hybrid coupler is approximately 40.1250˜88.1250 μm².

TABLE 1

| | | Bandwidth | |
|---|---|---|---|
| Component | Area (μm²) | (GHz) | Power Consumption |
| MZI as a | 60 × 180 | 28 | 100 pJ per FLOP |
| Matrix | (10800) | | |
| Computing | | | |
| Mesh | | | |
| mmW Matrix | 40.1250~ | 6 | 5-7.5fJ per FLOP or |
| Computing | 88.1250 | | 15-20fJ per FLOP |
| Mesh | | | depending on the |
| | | | capacitance value |

As shown from the comparison of the metrics in Table 1, the proposed mm-wave DLNN-FNN architecture as discussed herein outperforms its conventional PDLNN counterpart.

To further reduce the silicon area, FIG. 7 illustrates a schematic diagram of an input control block used in accordance with a computing network architecture, in accordance with the disclosure. The input control block 700 as shown in FIG. 7 may be identified with one of the input control blocks 108, as shown and discussed above with respect to FIG. 1, and which may form part of the input circuitry 102. The input control block 700 as shown in FIG. 7 is presented in a non-limiting and illustrative manner, and may include additional, alternate, or fewer components than those shown. As one example, the input control block 700 may omit the switching circuitry 704 if the training phase is intended to be performed separately and externally to the device in which the matrix computing network architecture 100 is implemented.

The input control block 700 may include a signal generator, switching circuitry 702, and switching circuitry 704. The signal generator 701 may be identified with the signal generator as shown in FIG. 1, and be implemented as a mm-Wave oscillator configured to generate a single tone mm-wave signal. The switching circuitry 702 may be implemented as a single pole double throw (SPDT) switch or any suitable components configured to perform signal switching at mm-wave frequencies, and is controlled by a PWM-driven digital data input that is in turn controlled via a control signal provided by the controller 150. The switching component of the switching circuitry 702 may be implemented as any suitable type of mm-wave compatible switching components, which should have a low insertion loss and good isolation between two switched paths.

The configuration as shown in FIG. 7 assumes that the input signals X1-XN comprise training signals. Thus, during the training phase as noted herein, each input to the interconnected computing matrices 104 may be off (e.g. coupled to a reference voltage such as the ground terminal), or coupled to the signal generator 701. When connected to the signal generator 701, the PWN control allows each input to be switched on and off rapidly, which may represent the input receiving a signal or not receiving the signal at its respective input at various times. As each input to the interconnected computing matrices 104 may be independently controlled as noted above, the use of PWM control in this manner may facilitate the different signal combinations being presented at each of the inputs X1-XN of the interconnected computing matrices 104 at different times.

Of course, the input control block 700 as shown in FIG. 7 may be modified to control other parameters of the training signal depending upon the particular application. Thus, the control signals provided by the controller 150 may adjust any suitable parameters of the training signals such as frequency, phase, amplitude, etc., depending upon the particular application and the type of signal that is to be received during the operating mode.

Additionally, the input control block 700 may include the switching circuitry 704, which may be implemented as a single pole single throw (SPST) switch or any suitable components configured to perform signal switching at mm-wave frequencies, and is also controlled via a control signal provided by the controller 150. The switching component of the switching circuitry 704 may likewise be implemented as any suitable type of mm-wave compatible switching components, which should have a low insertion loss and good isolation between two switched paths. The switching circuitry 704 may enable the controller 150 to couple the wirelessly received signals to the inputs of the interconnected computing matrices 104 as the input signals X1-XN during the operating mode, such as after the training phase has been completed as discussed above. The switching circuitry 702 may couple the signal generator 701 to ground during this time or the signal generator 701 may otherwise be deactivated.

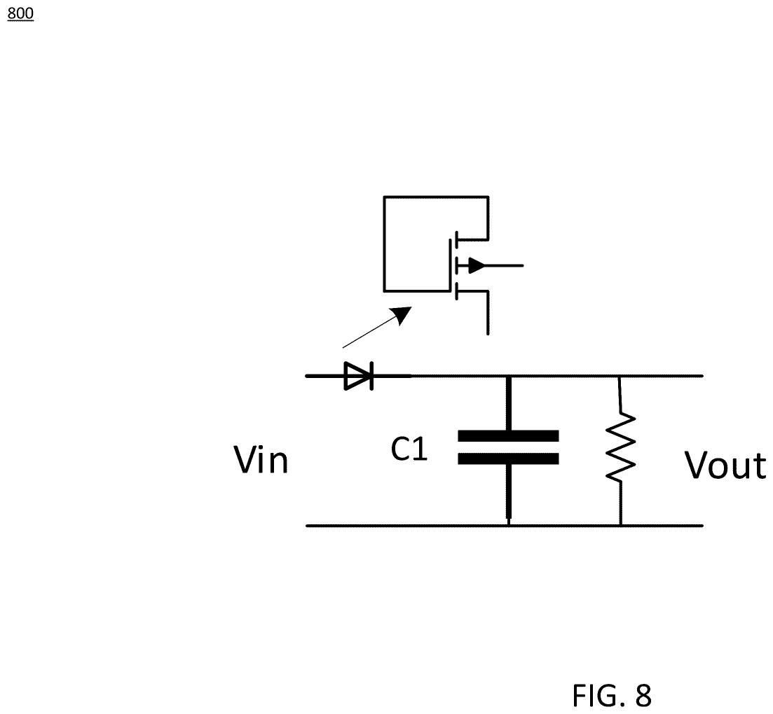

FIG. 8 illustrates a schematic diagram of an envelope detector used in accordance with a computing network architecture, in accordance with the disclosure. The envelope detector 800 as shown in FIG. 8 may be coupled to or otherwise be configured to measure an amplitude of the output signals H1-HN, and thus may form part of the output circuitry 106 as shown and discussed above with respect to FIG. 1. To do so, the controller 150 may measure the voltage Vout of each respective output signal H1-HN as the output signals pass through the envelope detector 800. The envelope detector 800 as shown in FIG. 8 is presented in a non-limiting and illustrative manner, and may include additional, alternate, or fewer components than those shown. The envelope detector 800 may replace the use of a conventional diode with an N-MOS or P-MOS controlled transistor as shown to provide a CMOS compatible solution.

As noted above for the input control block 700 as shown in FIG. 7, the envelope detector 800 may be modified to measure other parameters of the output signals H1-HN depending upon the particular application. Thus, the output circuitry 106 may include any suitable components to enable the controller to measure other parameters in addition to or instead of amplitude, such as frequency, phase, etc., depending upon the particular application and the type of signal that is to be output as the output signals H1-HN during the operating mode.

### II. Process Flows

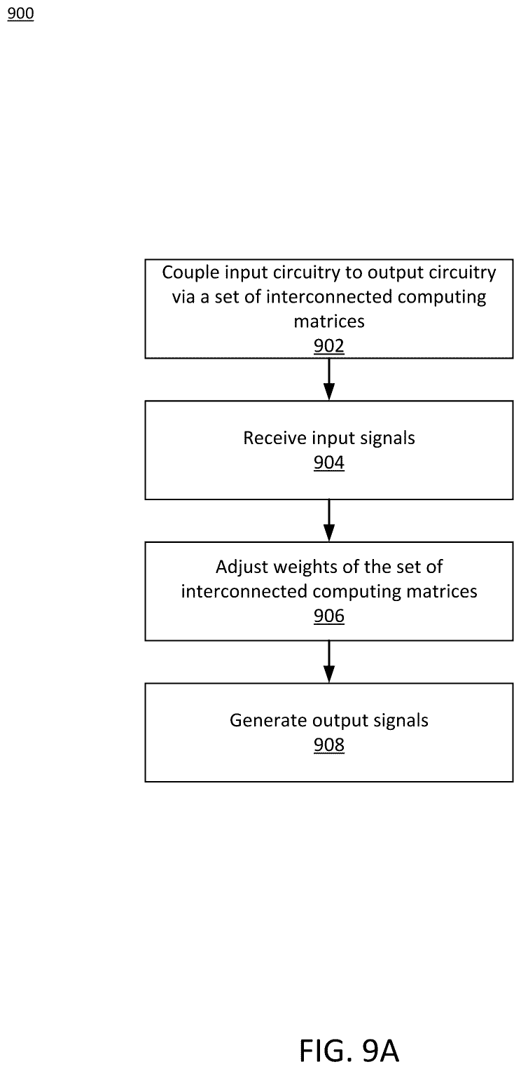

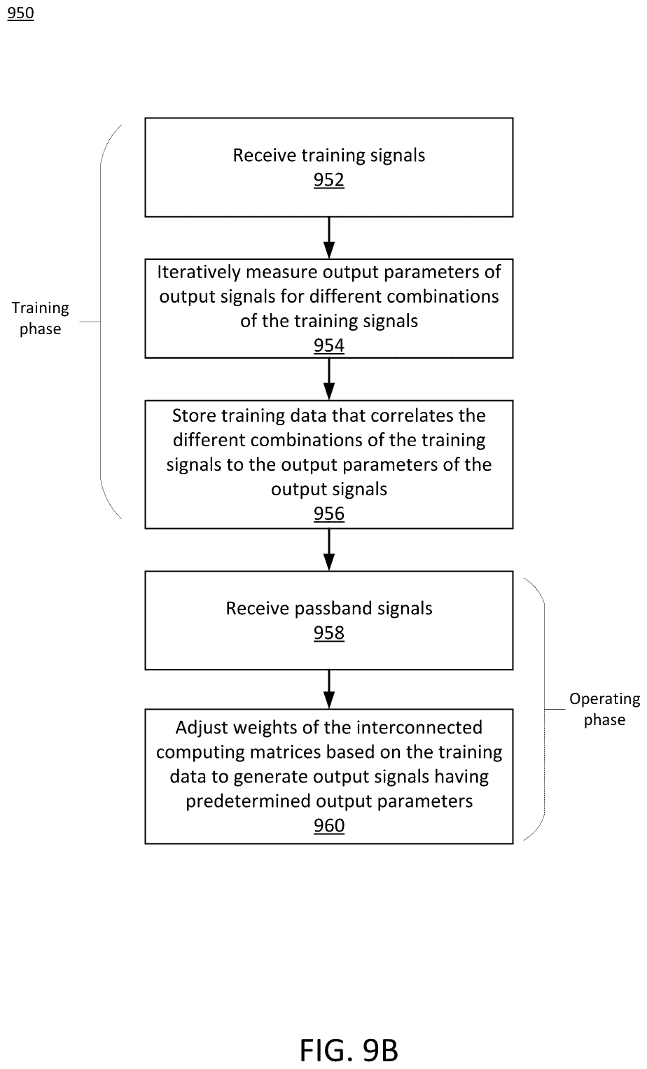

FIGS. 9A-9B illustrate process flows, in accordance with the disclosure. With reference to FIGS. 9A and 9B the flows 900, 950 may be manual processes, fully-automated processes, or partially-automated processes. When fully or partially-automated, any portion or the entirety of the flows 900, 950 may be implemented as a computer-implemented process executed by and/or otherwise associated with one or more processors. These processors may be associated with one or more computing components identified with any suitable computing device or architecture, such as a computing device or manufacturing component configured to perform such functionality. This computing device may be identified, in some non-limiting and illustrative scenarios, with the matrix computing network architecture 100 as discussed herein. Thus, in accordance with such scenarios, the controller 150 may execute instructions stored in any suitable memory (such as the memory 152) to perform or cause any components of the matrix computing network architecture 100 to perform any portions (or the entirety of) the process flows 900, 950. The process flows 900, 950 may include alternate or additional steps that are not shown in FIGS. 9A and 9B for purposes of brevity, and may be performed in a different order than the steps shown in FIGS. 9A and 9B.

With respect to FIG. 9A, the process flow 900 may begin by coupling (block 902) input circuitry to output circuitry via a set of interconnected computing matrices This may include, in a non-limiting and illustrative scenario, coupling the input circuitry 102 to the output circuitry 106 via the interconnected computing matrices 104, as discussed herein with respect to the matrix computing network architecture 100 as shown in FIG. 1. Thus, block 902 may comprise part of a CMOS fabrication and/or manufacturing process in which the matrix computing network architecture 100 is formed as part of a CMOS IC, a CMOS SoC, etc.

The process flow 900 may include receiving (block 904) input signals. This may include, in a non-limiting and illustrative scenario, receiving training signals or passband signals, as discussed herein.

The process flow 900 may include adjusting (block 906) weights of the set of interconnected computing matrices. This may include, in a non-limiting and illustrative scenario, providing an adjustable phase shift to phase shifters coupled to predetermined inputs and/or outputs of hybrid couplers of the matrix computing network architecture 100, as discussed herein. Again, the disclosure is not limited to the adjustment of phase in this manner, and thus this adjustment may include any suitable weight adjustment based upon the particular predetermined output signal parameters that are desired as a function of the input signals and their accompanying input signal parameters, as discussed herein.

The process flow 900 may include generating (block 908) output signals. This may include, in a non-limiting and illustrative scenario, generating the output signals via the output circuitry 106, as discussed herein with respect to the matrix computing network architecture 100 as shown in FIG. 1. This may include, in a non-limiting and illustrative scenario, generating the output signals having desired predetermined output signal parameters (such as amplitude) in response to the applied weights and combinations of the received input signals, as noted herein.

Turning now to FIG. 9B, both the training and operating modes are shown. Thus, the process flow 950 may begin by receiving (block 952) training signals. This may include, in a non-limiting and illustrative scenario, receiving the training signals via the input control blocks 108 that form part of the input circuitry 102, as discussed herein with respect to the matrix computing network architecture 100 as shown in FIG. 1.

The process flow 950 may include iteratively measuring (block 954) output parameters of output signals for different combinations of the training signals. This may include, in a non-limiting and illustrative scenario, adjusting the phase of various phase shifters in the interconnected computing matrices 104 to iterative adjust the weights thereof for different input signal combinations and/or input signal parameters, as discussed herein. Again, the weights may be adjusted in this manner via the adjustment of the phase shift provided by the phase shifters coupled to predetermined inputs and/or outputs of hybrid couplers of the matrix computing network architecture 100, as discussed herein. Again, the output parameters may comprise signal amplitude, phase, etc., as noted above.

This process may continue for any suitable combinations and/or iterations until a predetermined threshold number of iterations and/or combinations has been reached or the training data is otherwise identified as being complete. Once this is the case, process flow 950 may include storing (block 956) the training data in a suitable memory location, such as the memory 152. The training data may thus function to correlate the different training signal combinations and/or signal parameters of the training signals to different output parameters of the output signals as a function of the applied weights (such as phase shifts), as noted herein.

The blocks 952, 954, and 956 as shown in FIG. 9B may form at least part of the training phase, as discussed herein. Thus, once block 956 has been completed and the training data has been stored, the process flow 950 may include receiving (block 958) passband signals during the operating mode, as noted herein. This may include, in a non-limiting and illustrative scenario, receiving passband signals via the input control blocks 108 that form part of the input circuitry 102, as discussed herein with respect to the matrix computing network architecture 100 as shown in FIG. 1.

The process flow 950 may include adjusting (block 960) weights of the interconnected computing matrices based on the training data to thereby generate the output signals having predetermined output parameters. This may include, in a non-limiting and illustrative scenario, adjusting weights of the set of interconnected computing matrices 104 by providing an adjustable phase shift to phase shifters coupled to predetermined inputs and/or outputs of hybrid couplers of the matrix computing network architecture 100, as discussed herein. Again, the disclosure is not limited to the adjustment of phase in this manner, and thus this adjustment may include any suitable weight adjustment based upon the particular predetermined output signal parameters that are desired as a function of the input signals and their accompanying input signal parameters, as discussed herein. The output signals may comprise the output signals provided via the output circuitry 106, as discussed herein with respect to the matrix computing network architecture 100 as shown in FIG. 1. Again, this may include the output signals having desired predetermined output signal parameters (such as amplitude) in response to the applied weights and combinations of the received input signals, as noted herein.

### III. A Communication Device

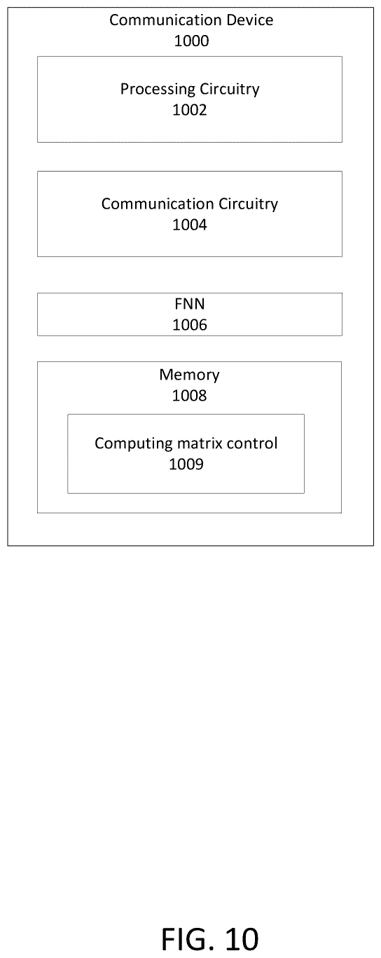

FIG. 10 illustrates a communication device, in accordance with the disclosure. The communication device 1000 may be identified with any suitable type of device that implements a computing network architecture, such as the matrix computing network architecture 100 as shown in FIG. 1 and discussed herein. The communication device 1000 may be identified with any suitable type of device that receives, transmits, and/or processes passband signals. Thus, the communication device 1000 may be identified with a wireless device, a user equipment (UE), a mobile phone, a tablet, a laptop computer, a wearable device, etc. Additionally or alternatively, and as further discussed herein, the communication device 1000 may be implemented as part of a multiple-input-multiple-output (MIMO) system used for communications in accordance with wireless device operation, as part of a radar system, etc.

The communication device 1000 may further comprise processing circuitry 1002, which may be configured as any suitable number and/or type of computer processors, and which may function to control the communication device 1000 and/or other components of the communication device 1000, such as the matrix computing network architecture 100. The processing circuitry 1002 may be identified with one or more processors (or suitable portions thereof) implemented by the communication device 1000. In a non-limiting and illustrative scenario, the processing circuitry 1002 may be identified with part of or the entirety of the controller 150, as shown and discussed above with respect to FIG. 1. The processing circuitry 1002 may be implemented as a host processor, a microcontroller, a digital signal processor, one or more microprocessors, a central processing unit (CPU), graphics processors such as a graphics processing unit (GPU), baseband processors, microcontrollers, an application-specific integrated circuit (ASIC), part (or the entirety of) a field-programmable gate array (FPGA), etc.

The processing circuitry 1002 may be configured to carry out instructions to perform arithmetical, logical, and/or input/output (I/O) operations, and/or to control the operation of one or more components of communication device 1000 to perform various functions as described herein. The processing circuitry 1002 may include one or more microprocessor cores, memory registers, buffers, clocks, etc., and may generate electronic control signals associated with the components of the communication device 1000 to control and/or modify the operation of these components. The processing circuitry 1002 may communicate with and/or control functions associated with the memory 1008, as well as any other components of the communication device 1000. Thus, the processing circuitry 1002 may control or cause other components to control the operation of the matrix computing network architecture 100, as discussed herein.

The communication device 1000 comprises communication circuitry 1004, which may comprise any suitable number and/or type of components configured to receive, condition, generate, transmit, and/or process signals associated with any suitable type of wireless communications. The communication circuitry 1004 may be coupled to one or more portions of the processing circuitry 1002 and/or the communication device 1000. The communication device 1000 may include any suitable type of components that are known to be associated with such communication functions, such as front-end components, antennas, buffers, mixers, oscillators, receivers, transmitters, transceivers, etc., as well as other suitable hardware components that may function in conjunction with such communication components, such as port, terminals, etc., which may be implemented to couple the communication circuitry 1004 to other suitable components and/or portions of the communication device 1000. The communication circuitry 1004 may be identified with portions of the matrix computing network architecture 100, such as the input circuitry 102 and/or output circuitry 106. Additionally or alternatively, the communication circuitry 1004 may be identified with any suitable components of the communication device 1000 depending upon the particular application and implementation of the communication device 1000.

The communication device 1000 comprises a feed forward neural network (FNN) 1006. In a non-limiting and illustrative scenario, the FNN 1006 may be identified with the matrix computing network architecture 100, as shown and discussed herein with respect to FIG. 1. Thus, the FNN 1006 may comprise any combination (or all) of the input circuitry 102, the output circuitry 106, and the interconnected computing matrices 104.

The memory 1008 is configured to store data and/or instructions such that, when executed by the processing circuitry 1002, cause the communication device 1000 to perform various functions such as controlling, monitoring, adjusting, and/or regulating the operation of the communication device 1000, which may include operation of the communication device 1000 during the training and operating modes as noted herein. In a non-limiting and illustrative scenario, the memory 1008 may be identified with part of or the entirety of the memory 152, as shown and discussed above with respect to FIG. 1. The memory 1008 may be implemented as any suitable type of volatile and/or non-volatile memory, including read-only memory (ROM), random access memory (RAM), flash memory, a magnetic storage media, an optical disc, erasable programmable read only memory (EPROM), programmable read only memory (PROM), etc.

The memory 1008 may be non-removable, removable, or a combination of both. The memory 1008 may be implemented as a non-transitory computer readable medium storing one or more executable instructions such as logic, algorithms, code, etc. The instructions, logic, code, etc., stored in the memory 1008 are represented by the various modules as shown. The processing circuitry 1002 may execute the instructions stored in the memory 1008, which are represented as the various modules and further discussed below, to enable any of the techniques as described herein to be functionally realized.

The computing matrix control module 1009 may store computer-readable instructions that, when executed by the processing circuitry 1002, enable the processing circuitry 1002 and/or the communication device 1000 to perform any of the functions as described herein with respect to the operation of the FNN 1006. Thus, the processing circuitry 1002 may execute the instructions stored in the computing matrix control module 1009 to perform training and to store the resulting training data in the memory 1008. Additionally or alternatively, the processing circuitry 1002 may execute the instructions stored in the computing matrix control module 1009 to adjust the weights of the FNN 1006, during the training and operating modes, to generate output control signals having predetermined signal parameters in response to received input signal combinations, as noted herein.

### IV. Implementations and Use Case Scenarios

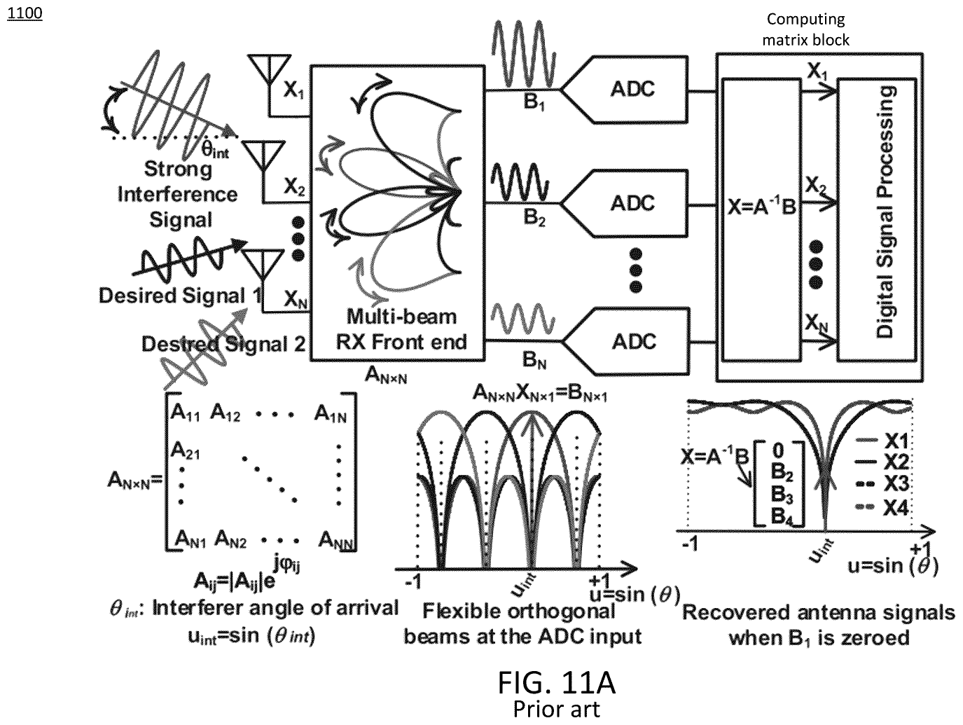

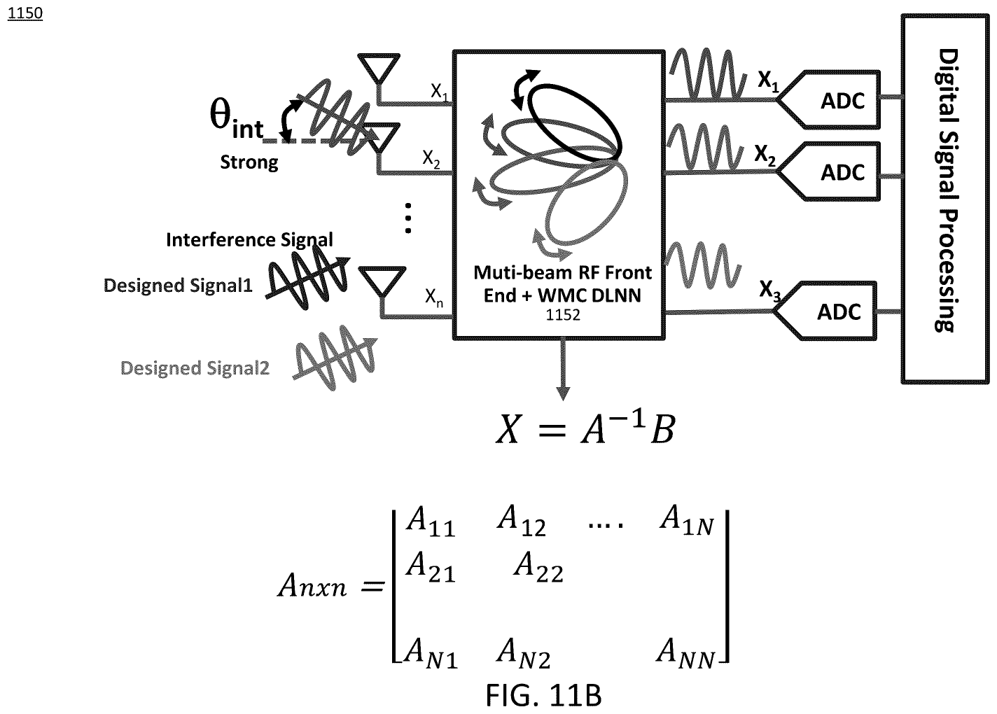

FIG. 11A illustrates a first type of conventional communication device. The communication device 1100 as shown in FIG. 11A may comprise a communication device that includes a massive MIMO system. The system as shown in FIG. 11A includes a set of antennas coupled to a multi-beam front end, which receives a signal X1-XN via each coupled antenna as shown. Thus, the front end outputs signals B1-BN in the analog domain, which may include conditioning such as amplification, down-conversion, filtering, etc. The signals B1-BN are then provided to a set of analog-to-digital converters (ADCs), which in turn digitize these signals B1-BN and provide the digitized signals to a digital computing matrix block. The digital computing matrix block may perform various operations such as the computation of an angle of arrival matrix A and perform digital signal processing using the inverse of this matrix to effectively zero out the interfering signal B1. However, such conventional systems perform the matrix computing after the ADCs, which demands the ADCs have a large dynamic range. Additionally, the digital computing matrix block consumes a significant amount of power to carry out these matrix computing operations.

FIG. 11B illustrates a first type of communication device implementing a matrix computing network architecture, in accordance with the disclosure. In a non-limiting and illustrative scenario, the communication device 1150 may be identified with the communication device 1000 as shown and discussed herein with respect to FIG. 10. Thus, the communication device 1150 as shown in FIG. 11B may also comprise a massive MIMO system that functions in a similar manner as the one shown and described above in FIG. 11A. However, the communication device 1150 as shown in FIG. 11B may implement an embedded wave matrix computing (WMC) DLNN 1152 to compute an angle of arrival matrix A and its inverse. The WMC DLNN 1152 may be implemented as, function in a similar or identical manner as, or otherwise be identified with the matrix computing network architecture 100. The WMC DLNN 1152 may be embedded in the RF front end and operate in the analog domain instead of the digital domain, as was the case for the conventional communication device 1100 as shown in FIG. 11A. In the system as shown in FIG. 11B, the embedded WMC DLNN 1152 may be implemented in this manner to receive the signals X1-XN as the passband signals via the input circuitry 102, and output the signals X1-X3 to the ADCs as the output signals provided via the output circuitry 106.

Thus, the WMC DLNN 1152 may be implemented to carry out both the training (during the training phase) and matrix computing (during the operational phase) to reduce the number of ADCs, reduce the dynamic range requirement of the ADCs, and to also reduce the computing power. Additionally, compared to conventional compute-in-memory (CiM) solutions, the implementation of the WMC DLNN 1152 has several advantages, including lower loss, increased bandwidth, and the ability to operate directly on the carrier signals before down conversion.

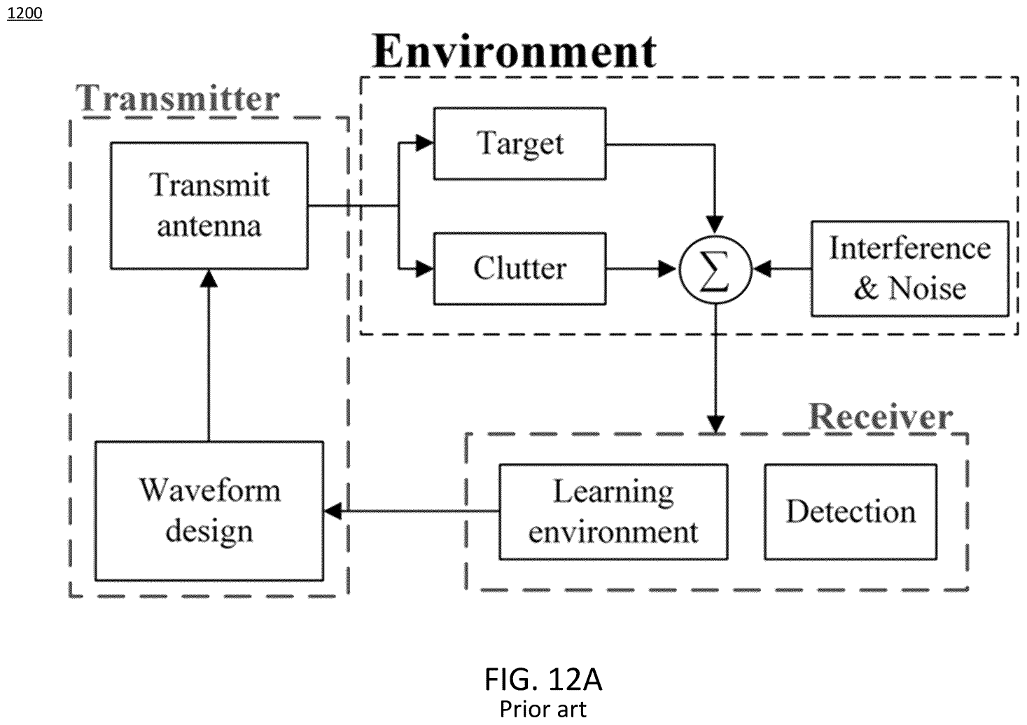

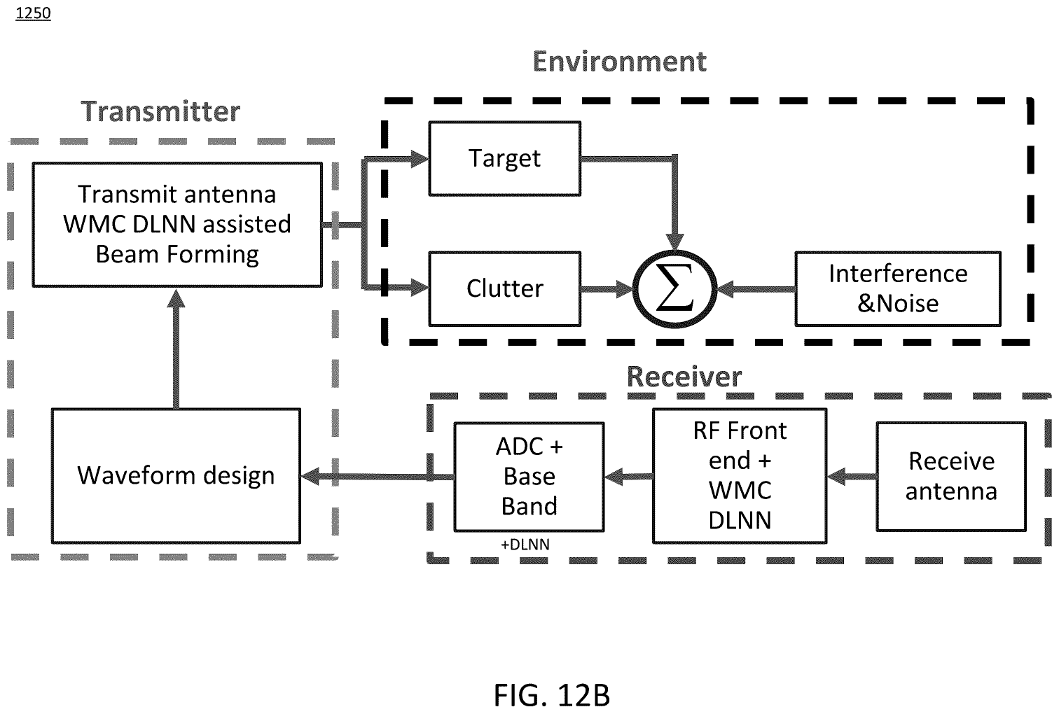

FIG. 12A illustrates a second type of conventional communication device. The communication device 1200 as shown in FIG. 12A may comprise a conventional communication device that includes a cognitive radar system. The system as shown in FIG. 12A includes a transmitter, a receiver, and a radar signal environment as shown. Thus, for this conventional cognitive radar system, all learnings are processed after the ADCs, which again requires a significant number of ADCs for computing and post-signal processing. The requirement for a larger number of ADCs is undesirable, as this leads to a very large overhead in terms of both area and power consumption. And to perform an accurate perception, the ADCs must meet high dynamic range requirements, which again translates into design engineering effort and cost.

FIG. 12B illustrates a second type of communication device implementing a matrix computing network architecture, in accordance with the disclosure. In a non-limiting and illustrative scenario, the communication device 1250 may be identified with the communication device 1000 as shown and discussed herein with respect to FIG. 10. The communication device 1250 as shown in FIG. 12B may also comprise a cognitive radar system that functions in a similar manner as the one shown and described above in FIG. 12A. However, the communication device 1250 as shown in FIG. 12B may implement one or more WMC DLNNs as shown. The WMC DLNNs may be implemented as, function in a similar or identical manner as, or otherwise be identified with the matrix computing network architecture 100.

In various non-limiting and illustrative scenarios, a WMC DLNN may be embedded as part of the RF front end in the receiver to facilitate intelligent waveform design by generating the desired output signals from signals received via the receive antenna. Additionally or alternatively, a WMC DLNN may be embedded as part of the transmitter to provide intelligent beamforming. Thus, in each case the WMC DLNN may operate in the analog domain and without down-conversion.

And for the cognitive radar system as shown in FIG. 12B, it is noted that the perception and learning occur in mm-wave domain before down-converting to the base band signal for transmit waveform control, and hence a lesser number of ADCs are needed. Moreover, not only may the number of ADCs be reduced, but the required dynamic range of the ADCs may be drastically reduced, so the design and implementation is also less costly. Furthermore, to form a hybrid learning system, an additional DLNN may be incorporated in baseband after the signal is down-converted, as shown in FIG. 12B.

### V. Simulations

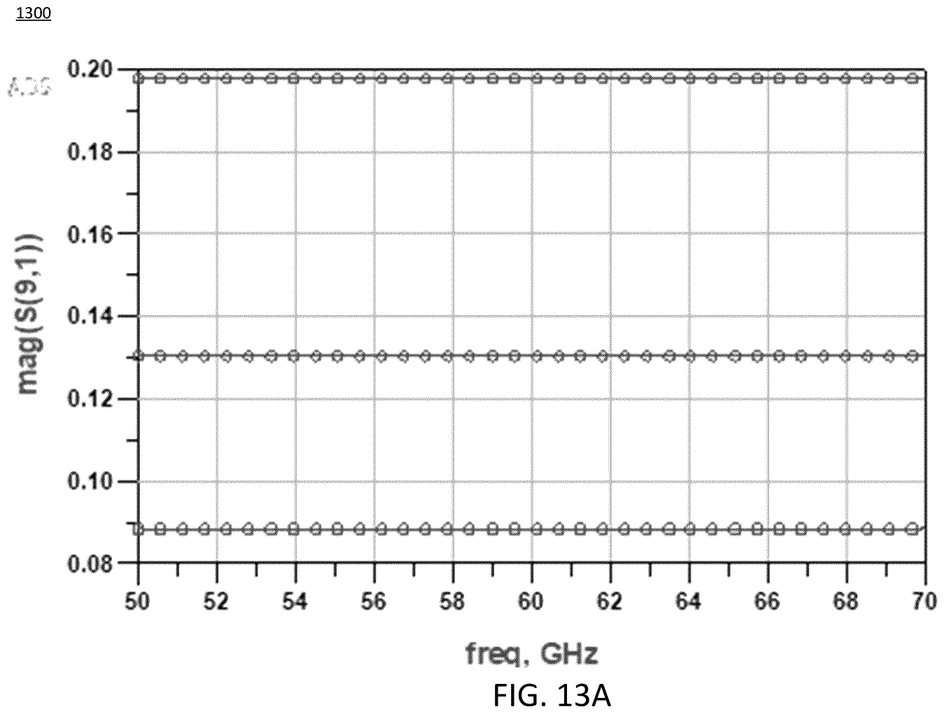

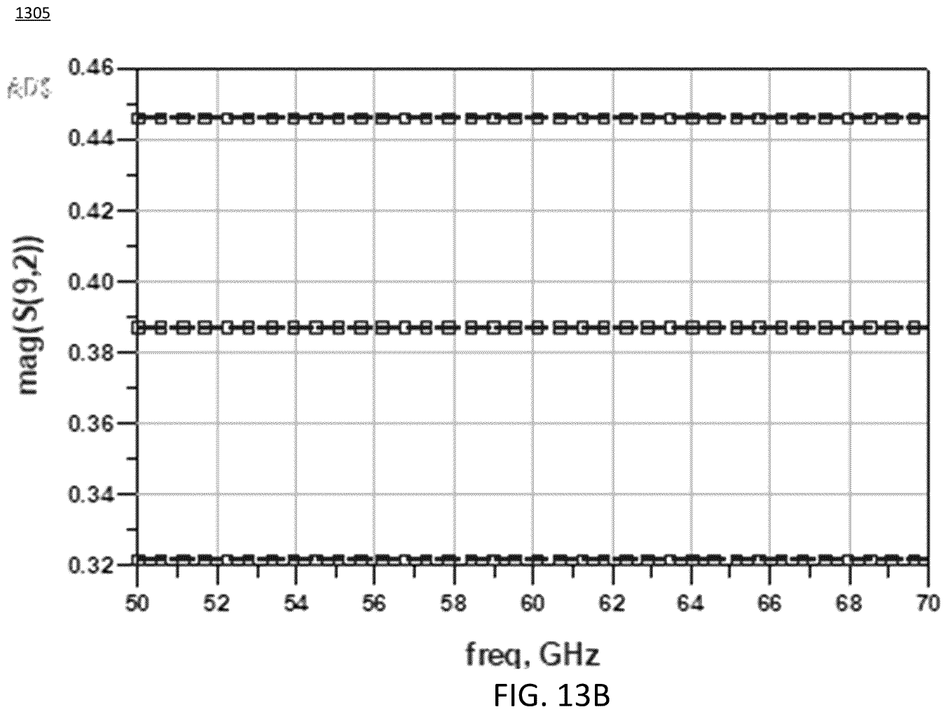

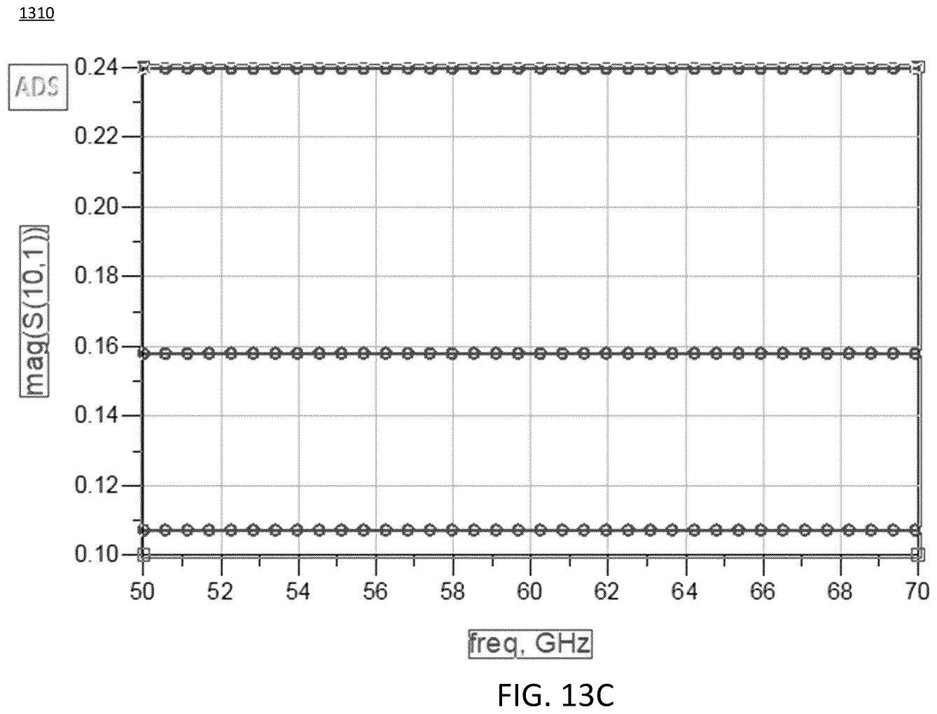

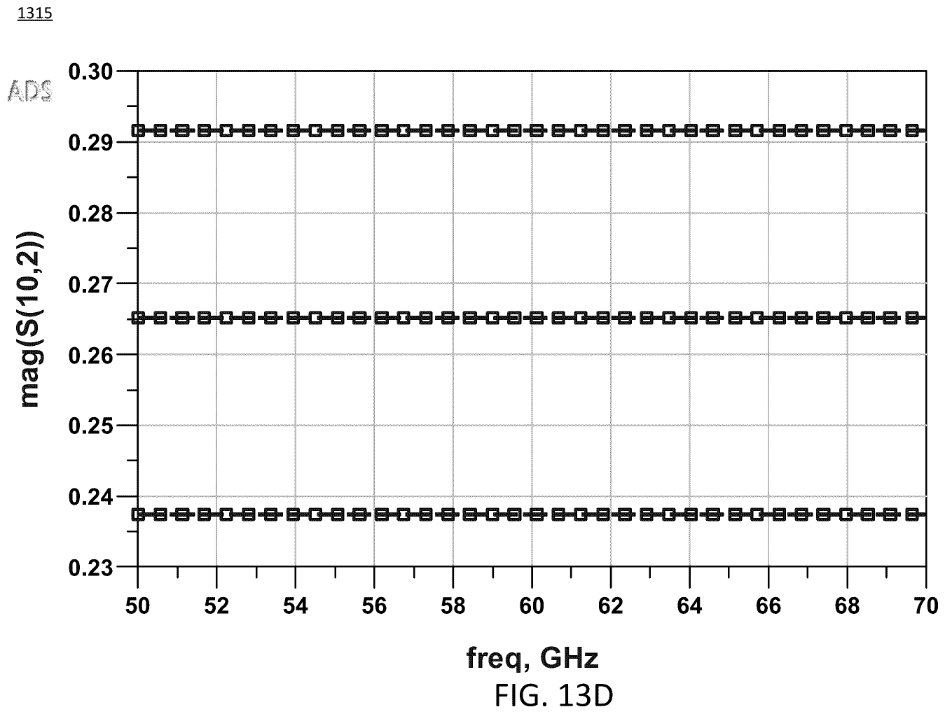

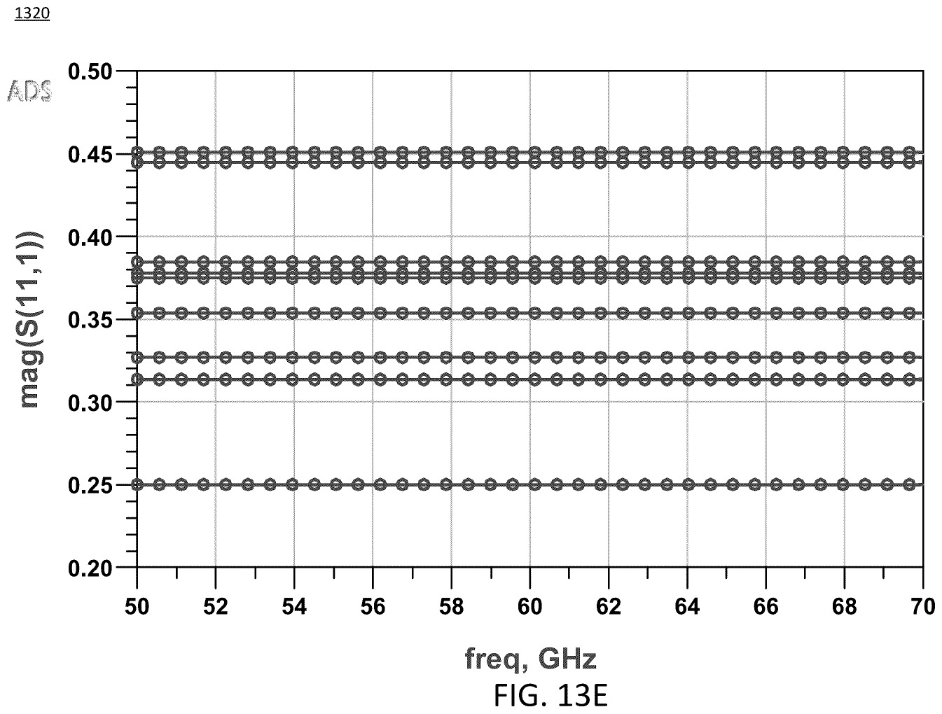

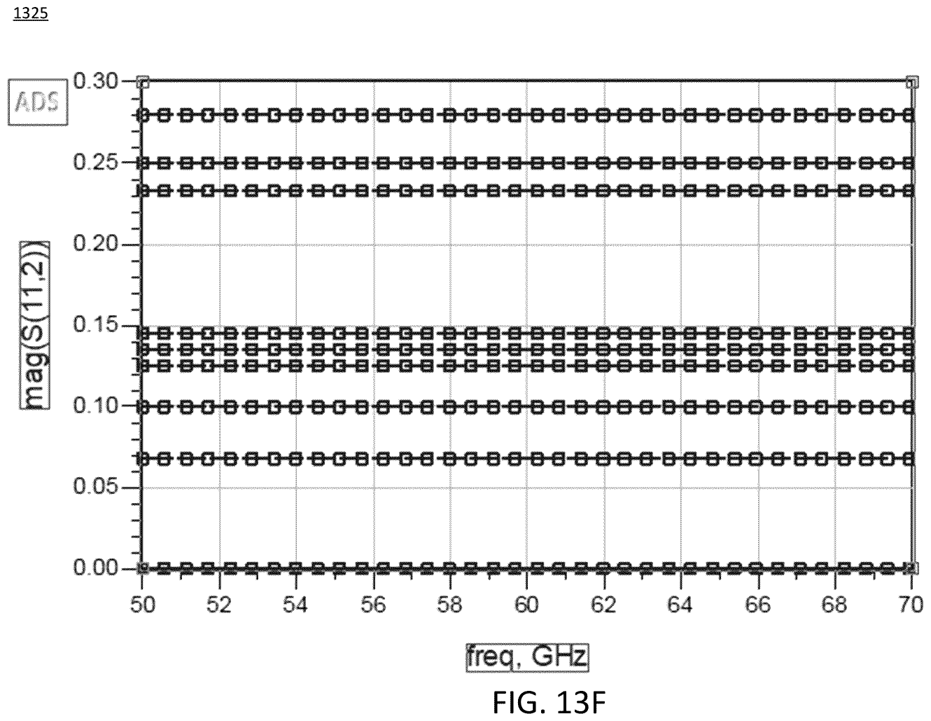

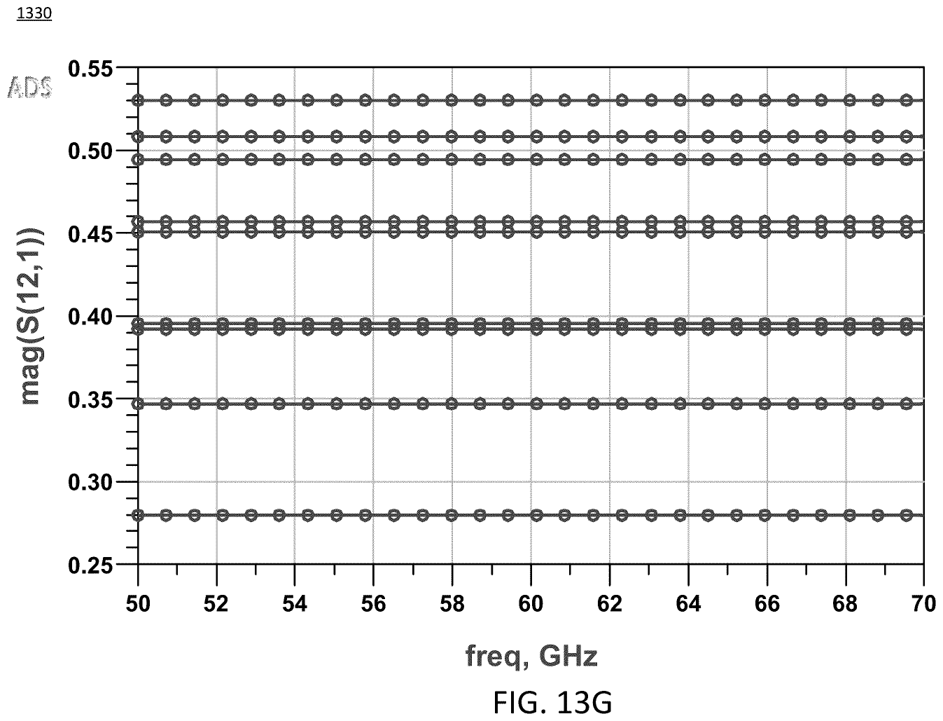

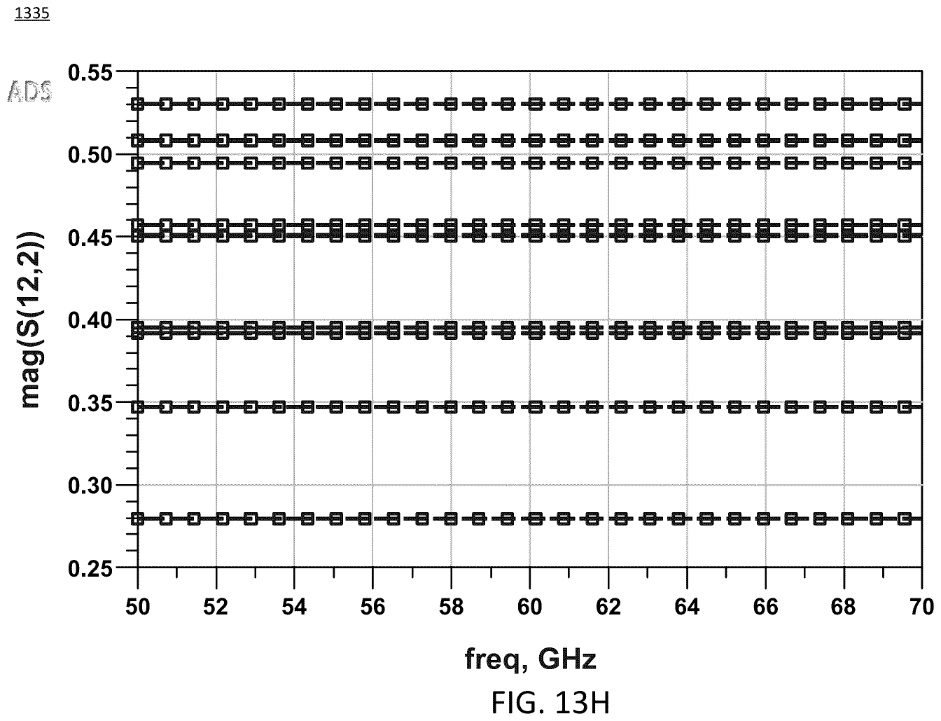

FIGS. 13A-13H illustrate weight control simulation results for various ports of a simulated 8×8 mm-wave FNN, in accordance with the disclosure. To do so, the matrix computing network architecture 100 was modeled as an 8×8 mm-wave FNN, as shown and discussed herein with respect to FIGS. 3A-3D, using an Advanced Design System (ADS) model to provide a weight control simulation.

Thus, and with respect to FIGS. 3A-3D, the simulation as shown in FIGS. 13A-13H illustrate S-parameter sweeps involving phase shifters φ11, φ12, and φ13. Specifically, while the phase shifter values are swept from 0° to 90° by 45° steps, the weights from Port 1 and Port 2 to Port 9, Port 10, Port 11, and Port 12 varied as shown in FIGS. 13A-13D. By examining the network as shown in FIGS. 3A-3B, the alteration of the phases φ11, φ12, and φ13 results in the adjustment of weights of some of the matrix computing meshes, such as those formed by HC11-HC12, HC11-HC22, HC22-HC33, etc.

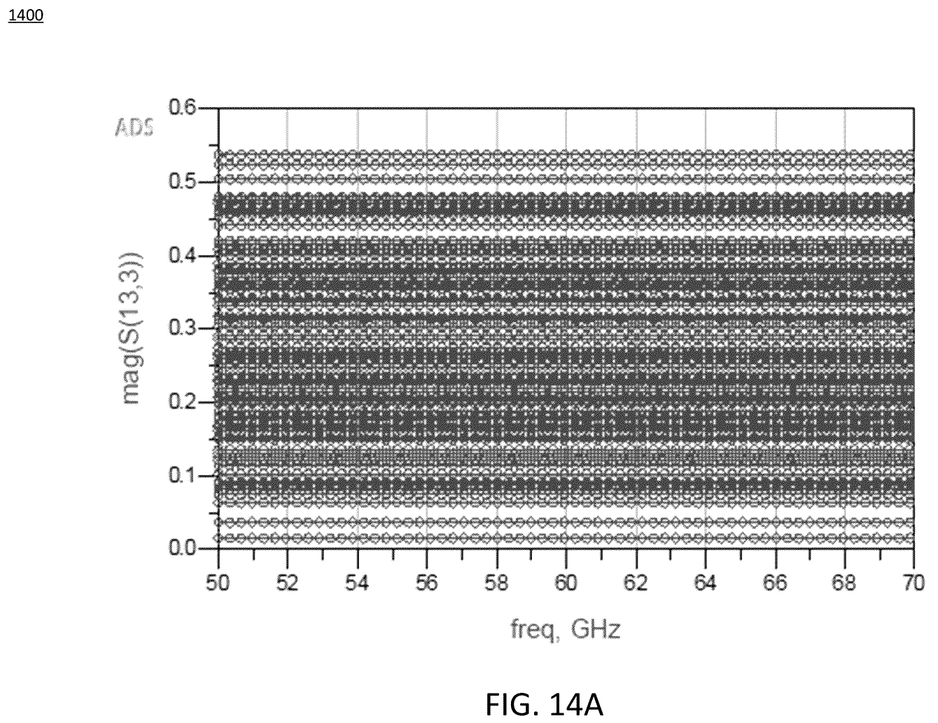

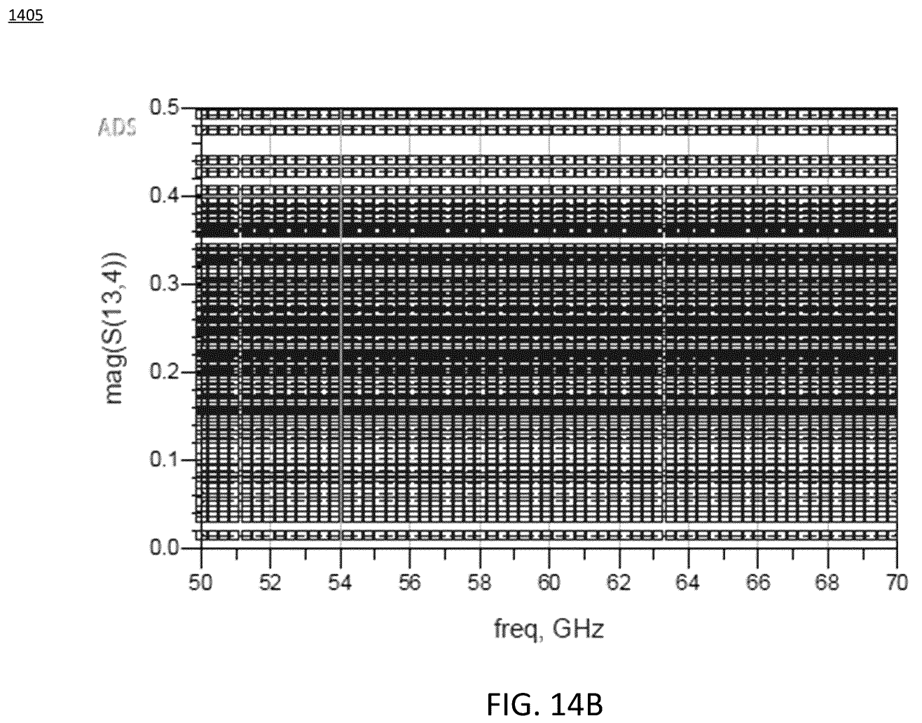

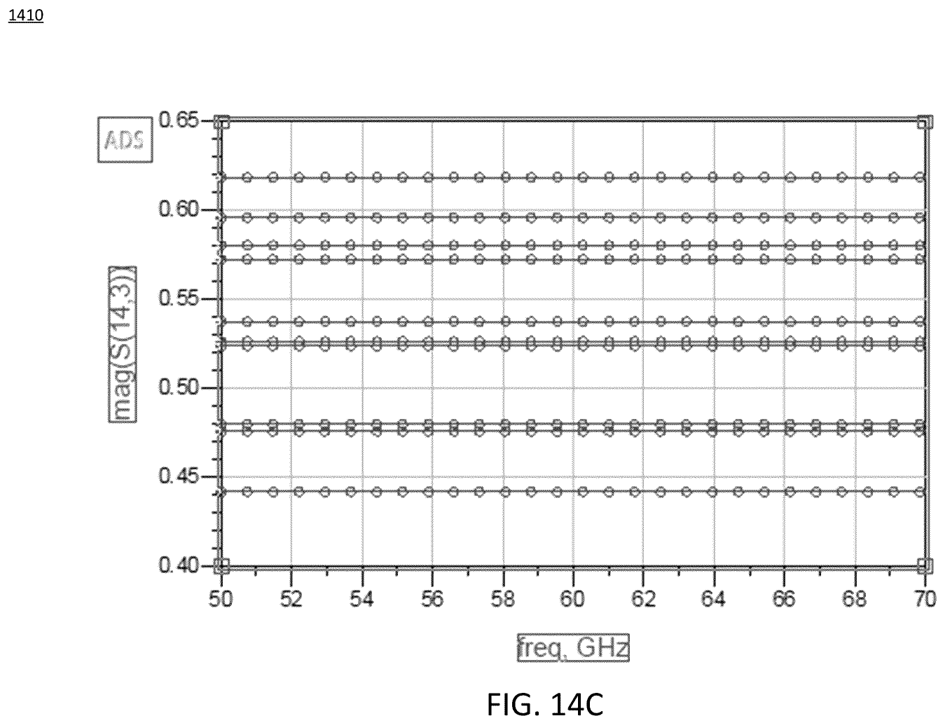

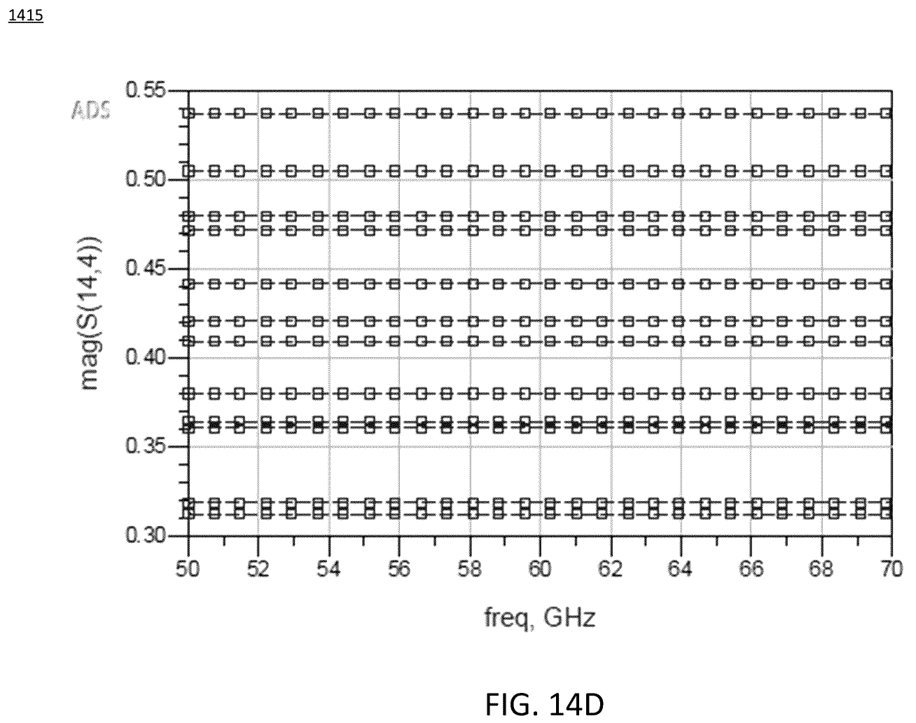

FIGS. 14A-14D illustrate additional weight control simulation results for various ports of a simulated 8×8 mm-wave FNN, in accordance with the disclosure. For the plots shown in FIGS. 14A-14D, another cluster of weight control simulations was conducted by varying φ21 and φ22 from 0° to 90° in 45° steps. Thus, FIGS. 14A-14D illustrate how the weights from Port 3 and Port 4 to Port 13 and Port 14 are adjusted with the phase changes through tuning those two phase shifters. The demonstrated weight controllability may be a function of the network formation. For instance, referring to FIGS. 3A-3B, tuning φ21 and φ22 varies the weights of the matrix computing meshes formed by HC12-HC22 as well as HC22-HC33, which can propagate towards Port 13 and Port 14.

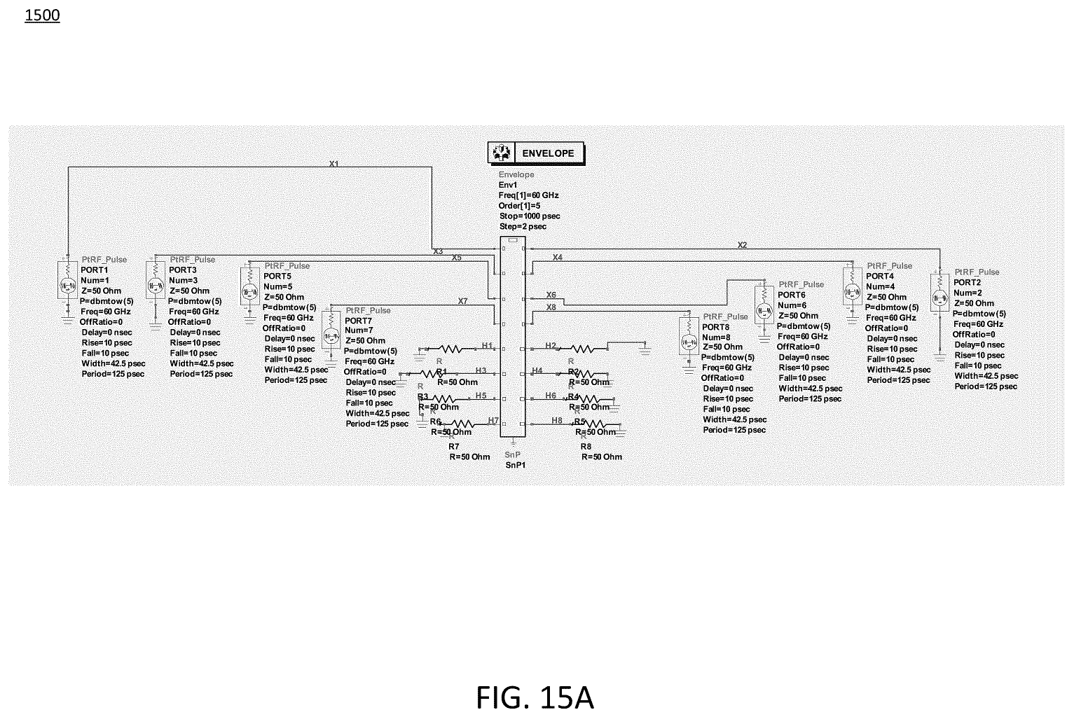

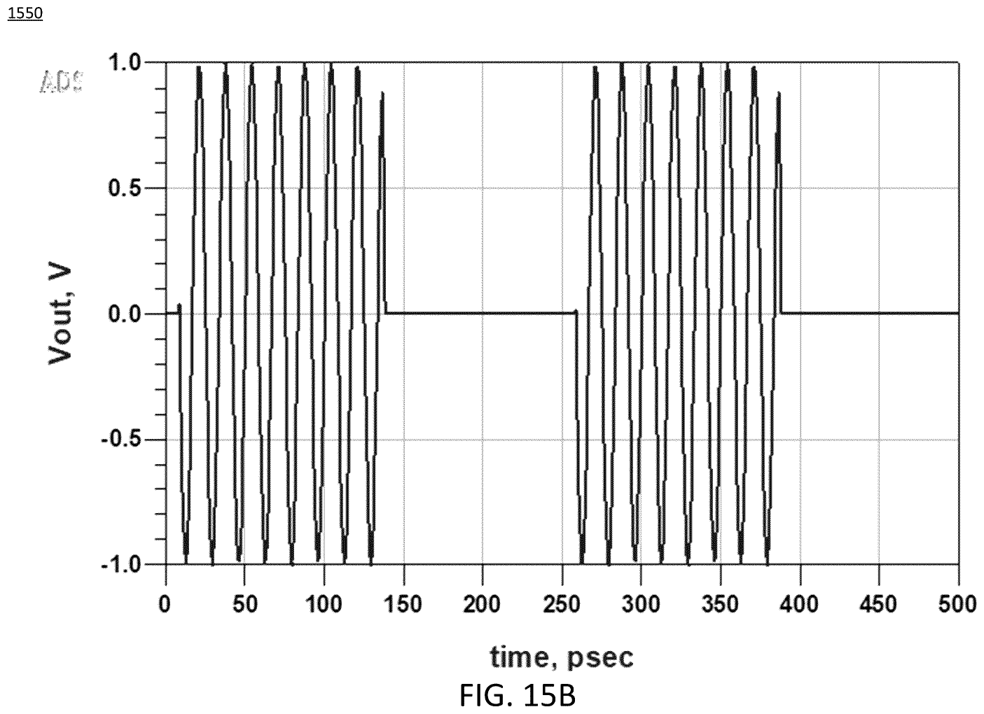

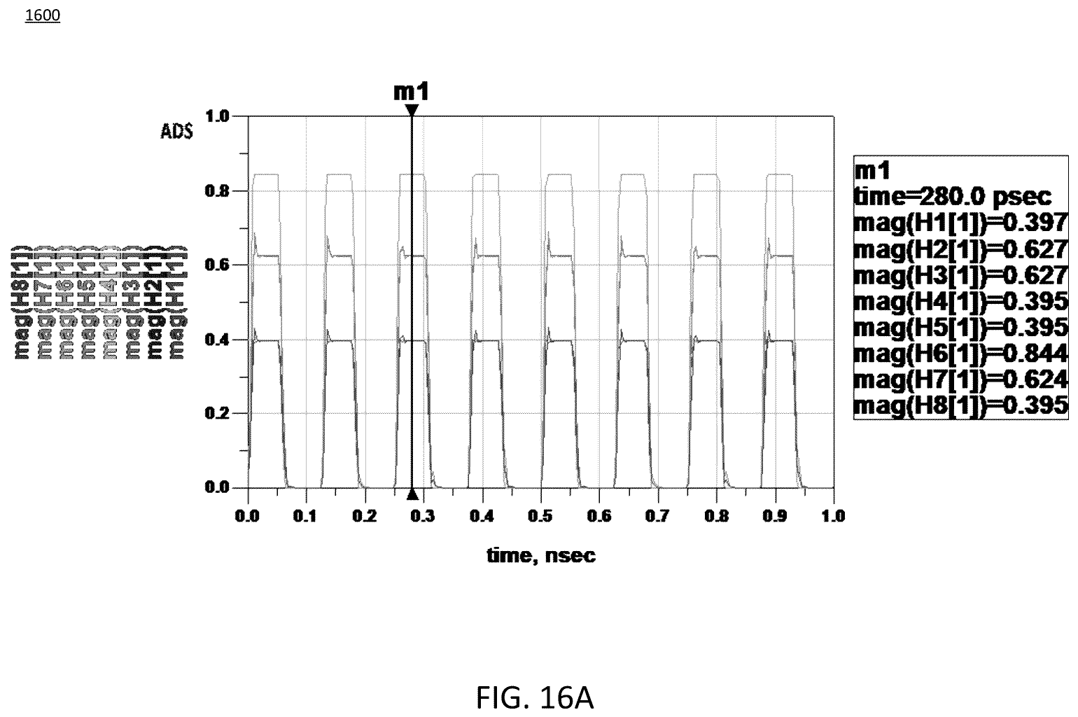

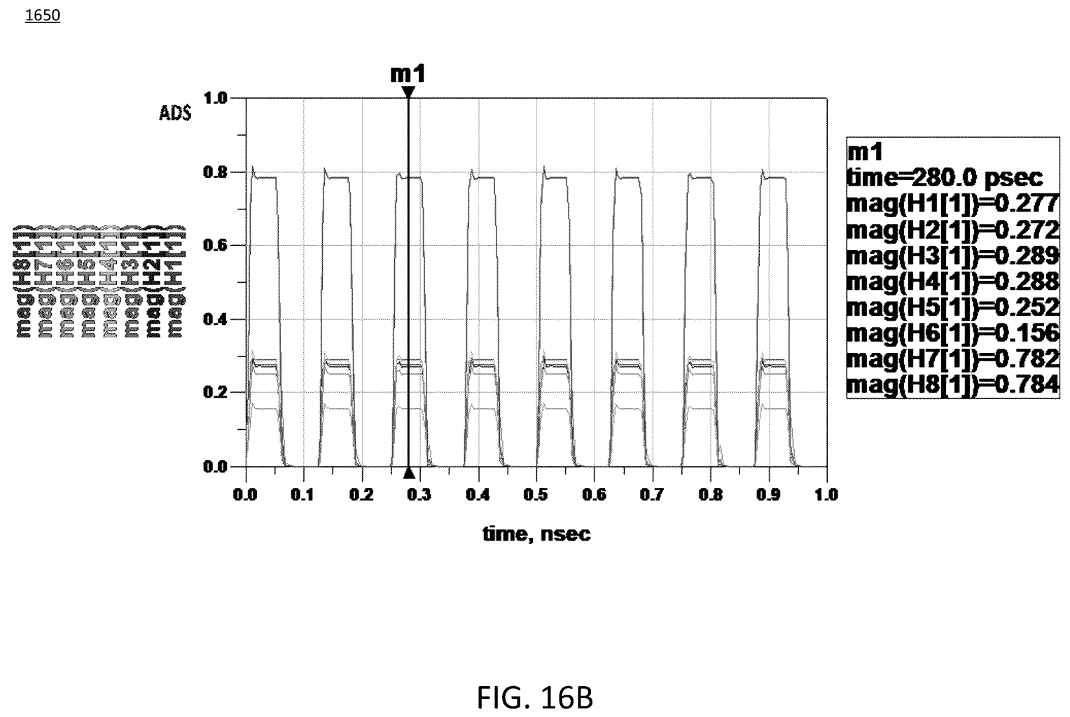

FIG. 15A illustrates an 8×8 mm-wave FNN computing speed simulation configuration, in accordance with the disclosure. That is, to demonstrate the computing speed of the 8×8 interweaving mm-wave FNN as discussed with respect to FIGS. 3A-3D, the S-parameters for two phase shifter configurations on the corresponding ADS modeled network were extracted and imported to the network as shown in FIG. 15A to perform an envelope simulation. In this setup, Xi is the ith input and Hi is the ith output. FIG. 15B illustrates an input waveform for the 8×8 mm-wave FNN computing speed simulation configuration as shown in FIG. 15A, in accordance with the disclosure. Thus, the input signal to the network model as shown in FIG. 15A is a pulse modulated signal as shown in FIG. 15B, which has a 60 GHz carrier frequency modulated by a 8 GHz pulse signal. The output signals were then simulated as being captured using envelope detection. The results of this simulation are discussed in further detail below with respect to FIGS. 16A and 16B.

FIGS. 16A-16B illustrate output signals for a simulated 8×8 mm-wave FNN with two different phase shifter configurations, in accordance with the disclosure. Thus, the output signals as shown in FIGS. 16A-16B are the result of the simulation of the output signals using envelope detection, as discussed above with respect to FIGS. 15A-15B. With continued reference to FIGS. 16A-16B, via the use of simulated envelope detection, the output waveforms at each output port are captured using 2 different phase shifter configurations. This clearly indicates that the 8×8 mm-Wave FNN can perform 8×8 matrix computing at a clock frequency of 8 GHZ, hence the throughput can be as high as 1.025 TOPs, which exceeds the throughput of some GPU products in the sense of computing speed.

Similarly, for the FNN 200 as shown in FIGS. 2A-2B, the clock frequency may be 8 GHZ, so the achievable computing speed varies from 0.256 TOP for a 4×4 network to 1.025 TOPs for a 8×8 network. Moreover, the proposed 8×8 mm-wave FNN as discussed herein may be used as a basic unit to form more larger DLNNs to further increase the computing throughput.

FIG. 17A illustrates a model and simulation setup for a CMOS compatible lumped element hybrid coupler, in accordance with the disclosure. Again, and referring now back to FIGS. 4 and 5, it is noted that for a matrix computing mesh to work well within a mm-wave FNN, the hybrid coupler's SINDR should meet or exceed a particular criterion. Specifically, the hybrid coupler should have a bandwidth defined as a frequency band within which the SINDR meets a predefined requirement. The hybrid coupler as shown in FIG. 4 was thus modeled via ADS modeling for the purpose of providing the simulations discussed above, and this model is shown in FIG. 17A. To illustrate that the hybrid coupler is sufficient, FIG. 17B illustrates the performance of the model CMOS compatible lumped element hybrid coupler as shown in FIG. 17A, in accordance with the disclosure.

### VI. General Operation of an Apparatus

An apparatus is provided. The apparatus comprises input circuitry configured to receive one or more input signals; output circuitry configured to output one or more output signals; and a complementary metal oxide semiconductor (CMOS) integrated circuit (IC) comprising a set of interconnected computing matrices configured to couple the input circuitry and the output circuitry to one another, the set of interconnected computing matrices comprises a set of hybrid couplers and a set of adjustable phase shifters, the set of adjustable phase shifters configured to provide an adjustable phase shift to generate the one or more output signals. In addition or in alternative to and in any combination with the optional features previously explained in this paragraph, the one or more input signals and the one or more output signals further comprise millimeter wave carrier frequencies. In addition or in alternative to and in any combination with the optional features previously explained in this paragraph, the set of interconnected computing matrices are configured to generate the one or more output signals based on predetermined combinations of the one or more input signals. In addition or in alternative to and in any combination with the optional features previously explained in this paragraph, the set of adjustable phase shifters is configured to provide the adjustable phase shift based at least on predetermined combinations of the one or more input signals as a function of phase shift value weights. In addition or in alternative to and in any combination with the optional features previously explained in this paragraph, the output circuitry comprises a set of envelope detectors configured to measure a respective amplitude of the one or more output signals, and the measured respective amplitude is used to determine whether an amplitude of the one or more output signals is within a threshold range. In addition or in alternative to and in any combination with the optional features previously explained in this paragraph, a computing matrix of the set of interconnected computing matrices comprises two hybrid couplers and two adjustable phase shifters, a first one of the two adjustable phase shifters is coupled to a first port of a first one of the two hybrid couplers, and a second one of the two adjustable phase shifters is coupled to a second port of the first one of the two hybrid couplers and to a first port of the second one of the two hybrid couplers. In addition or in alternative to and in any combination with the optional features previously explained in this paragraph, the set of hybrid couplers comprises one or more CMOS IC lumped element hybrid couplers. In addition or in alternative to and in any combination with the optional features previously explained in this paragraph, the set of interconnected computing matrices are interconnected via CMOS IC transmission lines. In addition or in alternative to and in any combination with the optional features previously explained in this paragraph, the input circuitry comprises a set of carrier frequency signal generators configured to selectively couple a respective one of the one or more input signals to the input circuitry to generate different input signal combinations

### VII. General Operation of a Communication Device

A communication device is provided, the communication devices comprises communication circuitry configured to receive one or more signals; a complementary metal oxide semiconductor (CMOS) integrated circuit (IC) comprising a feedforward neural network (FNN) including a set of interconnected computing matrices configured to generate one or more output signals based upon the one or more received signals; and processing circuitry configured to control a phase shift of a set of adjustable phase shifters associated with the set of interconnected computing matrices to generate the one or more output signals based upon the one or more received signals. In addition or in alternative to and in any combination with the optional features previously explained in this paragraph, the processing circuitry is configured to adjust the phase shift of the set of adjustable phase shifters based on an amplitude of the one or more received signals. In addition or in alternative to and in any combination with the optional features previously explained in this paragraph, further comprising: a set of carrier signal generators configured, as part of a training process that generates signal training data, to selectively couple a respective one of the one or more received signals to different signal inputs of the communication device to generate different predetermined combinations of the one or more received signals. In addition or in alternative to and in any combination with the optional features previously explained in this paragraph, the one or more received signals and the one or more output signals further comprise millimeter wave carrier frequencies. In addition or in alternative to and in any combination with the optional features previously explained in this paragraph, the processing circuitry is configured to generate the one or more output signals comprising predetermined output signal amplitudes based upon predetermined combinations of the one or more received signals. In addition or in alternative to and in any combination with the optional features previously explained in this paragraph, further comprising: a set of envelope detectors configured to measure a respective amplitude of the one or more output signals, the processing circuitry is configured to determine, based upon the measured amplitude of the one or more output signals, whether a respective amplitude of the one or more output signals is within a threshold range. In addition or in alternative to and in any combination with the optional features previously explained in this paragraph: a computing matrix of the set of interconnected computing matrices comprises two hybrid couplers and two adjustable phase shifters, a first one of the two adjustable phase shifters is coupled to a first port of a first one of the two hybrid couplers, and a second one of the two adjustable phase shifters is coupled to a second port of the first one of the two hybrid couplers and to a first port of the second one of the two hybrid couplers. In addition or in alternative to and in any combination with the optional features previously explained in this paragraph, the set of interconnected computing matrices comprise an interconnected set of lumped element hybrid couplers. In addition or in alternative to and in any combination with the optional features previously explained in this paragraph, the CMOS IC further comprises transmission lines, and the set of interconnected computing matrices are interconnected via the transmission lines.

### VIII. General Operation of a Non-Transitory Computer-Readable Medium

At least one non-transitory computer-readable medium is provided, The least one non-transitory computer-readable medium comprises instructions stored thereon, that if executed by one or more processors, cause the one or more processors to: receive one or more input signals via input circuitry; output one or more output signals via output circuitry, the input circuitry and the output circuitry are coupled to one another via a set of interconnected computing matrices included as part of a complementary metal oxide semiconductor (CMOS) integrated circuit (IC), and control a phase shift value of a set of adjustable phase shifters associated with the set of interconnected computing matrices to generate the one or more output signals based upon the one or more received signals. In addition or in alternative to and in any combination with the optional features previously explained in this paragraph, the instructions, if executed by one or more processors, further cause the one or more processors to control the phase shift of the set of adjustable phase shifters based on an amplitude of the one or more received signals.

### EXAMPLES

The following examples pertain to further aspects.

An example (e.g. example 1) is directed to an apparatus comprising: input circuitry configured to receive one or more input signals; output circuitry configured to output one or more output signals; and a complementary metal oxide semiconductor (CMOS) integrated circuit (IC) comprising a set of interconnected computing matrices configured to couple the input circuitry and the output circuitry to one another, wherein the set of interconnected computing matrices comprises a set of hybrid couplers and a set of adjustable phase shifters, the set of adjustable phase shifters configured to provide an adjustable phase shift to generate the one or more output signals.

Another example (e.g. example 2), relates to a previously-described example (e.g. example 1), wherein the one or more input signals and the one or more output signals further comprise millimeter wave carrier frequencies.

Another example (e.g. example 3) relates to a previously-described example (e.g. one or more of examples 1-2), wherein the set of interconnected computing matrices are configured to generate the one or more output signals based on predetermined combinations of the one or more input signals.

Another example (e.g. example 4) relates to a previously-described example (e.g. one or more of examples 1-3), wherein the set of adjustable phase shifters is configured to provide the adjustable phase shift based at least on predetermined combinations of the one or more input signals as a function of phase shift value weights.

Another example (e.g. example 5) relates to a previously-described example (e.g. one or more of examples 1-4), wherein the output circuitry comprises a set of envelope detectors configured to measure a respective amplitude of the one or more output signals, and wherein the measured respective amplitude is used to determine whether an amplitude of the one or more output signals is within a threshold range.

Another example (e.g. example 6) relates to a previously-described example (e.g. one or more of examples 1-5), wherein: a computing matrix of the set of interconnected computing matrices comprises two hybrid couplers and two adjustable phase shifters, a first one of the two adjustable phase shifters is coupled to a first port of a first one of the two hybrid couplers, and a second one of the two adjustable phase shifters is coupled to a second port of the first one of the two hybrid couplers and to a first port of the second one of the two hybrid couplers.

Another example (e.g. example 7) relates to a previously-described example (e.g. one or more of examples 1-6), wherein the set of hybrid couplers comprises one or more CMOS IC lumped element hybrid couplers.

Another example (e.g. example 8) relates to a previously-described example (e.g. one or more of examples 1-7), wherein the set of interconnected computing matrices are interconnected via CMOS IC transmission lines.

Another example (e.g. example 9) relates to a previously-described example (e.g. one or more of examples 1-8), wherein the input circuitry comprises a set of carrier frequency signal generators configured to selectively couple a respective one of the one or more input signals to the input circuitry to generate different input signal combinations.

An example (e.g. example 10) is directed to communication device, comprising: communication circuitry configured to receive one or more signals; a complementary metal oxide semiconductor (CMOS) integrated circuit (IC) comprising a feedforward neural network (FNN) including a set of interconnected computing matrices configured to generate one or more output signals based upon the one or more received signals; and processing circuitry configured to control a phase shift of a set of adjustable phase shifters associated with the set of interconnected computing matrices to generate the one or more output signals based upon the one or more received signals.

Another example (e.g. example 11), relates to a previously-described example (e.g. example 10), wherein the processing circuitry is configured to adjust the phase shift of the set of adjustable phase shifters based on an amplitude of the one or more received signals.

Another example (e.g. example 12) relates to a previously-described example (e.g. one or more of examples 10-11), further comprising: a set of carrier signal generators configured, as part of a training process that generates signal training data, to selectively couple a respective one of the one or more received signals to different signal inputs of the communication device to generate different predetermined combinations of the one or more received signals.

Another example (e.g. example 13) relates to a previously-described example (e.g. one or more of examples 10-12), wherein the one or more received signals and the one or more output signals further comprise millimeter wave carrier frequencies.

Another example (e.g. example 14) relates to a previously-described example (e.g. one or more of examples 10-13), wherein the processing circuitry is configured to generate the one or more output signals comprising predetermined output signal amplitudes based upon predetermined combinations of the one or more received signals.

Another example (e.g. example 15) relates to a previously-described example (e.g. one or more of examples 10-14), further comprising: a set of envelope detectors configured to measure a respective amplitude of the one or more output signals, wherein the processing circuitry is configured to determine, based upon the measured amplitude of the one or more output signals, whether a respective amplitude of the one or more output signals is within a threshold range.

Another example (e.g. example 16) relates to a previously-described example (e.g. one or more of examples 10-15), wherein: a computing matrix of the set of interconnected computing matrices comprises two hybrid couplers and two adjustable phase shifters, a first one of the two adjustable phase shifters is coupled to a first port of a first one of the two hybrid couplers, and a second one of the two adjustable phase shifters is coupled to a second port of the first one of the two hybrid couplers and to a first port of the second one of the two hybrid couplers.

Another example (e.g. example 17) relates to a previously-described example (e.g. one or more of examples 10-16), wherein the set of interconnected computing matrices comprise an interconnected set of lumped element hybrid couplers.

Another example (e.g. example 18) relates to a previously-described example (e.g. one or more of examples 10-17), wherein the CMOS IC further comprises transmission lines, and wherein the set of interconnected computing matrices are interconnected via the transmission lines.

An example (e.g. example 19) is directed to at least one non-transitory computer-readable medium comprising instructions stored thereon, that if executed by one or more processors, cause the one or more processors to: receive one or more input signals via input circuitry; output one or more output signals via output circuitry, wherein the input circuitry and the output circuitry are coupled to one another via a set of interconnected computing matrices included as part of a complementary metal oxide semiconductor (CMOS) integrated circuit (IC), and control a phase shift value of a set of adjustable phase shifters associated with the set of interconnected computing matrices to generate the one or more output signals based upon the one or more received signals.

Another example (e.g. example 20) relates to a previously-described example (e.g. example 19), wherein the instructions, if executed by one or more processors, further cause the one or more processors to control the phase shift of the set of adjustable phase shifters based on an amplitude of the one or more received signals.

An example (e.g. example 21) is directed to an apparatus comprising: input means for receiving one or more input signals; output circuitry means for outputting one or more output signals; and a complementary metal oxide semiconductor (CMOS) integrated circuit (IC) comprising a set of interconnected computing matrices configured to couple the input means and the output means to one another, wherein the set of interconnected computing matrices comprises a set of hybrid couplers and a set of adjustable phase shifters, the set of adjustable phase shifters configured to provide an adjustable phase shift to generate the one or more output signals.

Another example (e.g. example 22), relates to a previously-described example (e.g. example 11), wherein the one or more input signals and the one or more output signals further comprise millimeter wave carrier frequencies.

Another example (e.g. example 23) relates to a previously-described example (e.g. one or more of examples 21-22), wherein the set of interconnected computing matrices are configured to generate the one or more output signals based on predetermined combinations of the one or more input signals.

Another example (e.g. example 24) relates to a previously-described example (e.g. one or more of examples 21-23), wherein the set of adjustable phase shifters is configured to provide the adjustable phase shift based at least on predetermined combinations of the one or more input signals as a function of phase shift value weights.

Another example (e.g. example 25) relates to a previously-described example (e.g. one or more of examples 21-24), wherein the output means comprises a set of envelope detectors configured to measure a respective amplitude of the one or more output signals, and wherein the measured respective amplitude is used to determine whether an amplitude of the one or more output signals is within a threshold range.

Another example (e.g. example 26) relates to a previously-described example (e.g. one or more of examples 21-25), wherein: a computing matrix of the set of interconnected computing matrices comprises two hybrid couplers and two adjustable phase shifters, a first one of the two adjustable phase shifters is coupled to a first port of a first one of the two hybrid couplers, and a second one of the two adjustable phase shifters is coupled to a second port of the first one of the two hybrid couplers and to a first port of the second one of the two hybrid couplers.

Another example (e.g. example 27) relates to a previously-described example (e.g. one or more of examples 21-26), wherein the set of hybrid couplers comprises one or more CMOS IC lumped element hybrid couplers.

Another example (e.g. example 28) relates to a previously-described example (e.g. one or more of examples 21-27), wherein the set of interconnected computing matrices are interconnected via CMOS IC transmission lines.

Another example (e.g. example 29) relates to a previously-described example (e.g. one or more of examples 21-28), wherein the input means comprises a set of carrier frequency signal generators configured to selectively couple a respective one of the one or more input signals to the input means to generate different input signal combinations.

An example (e.g. example 30) is directed to communication device, comprising: communication means for receiving one or more signals; a complementary metal oxide semiconductor (CMOS) integrated circuit (IC) comprising a feedforward neural network (FNN) including a set of interconnected computing matrices configured to generate one or more output signals based upon the one or more received signals; and processing means for controlling a phase shift of a set of adjustable phase shifters associated with the set of interconnected computing matrices to generate the one or more output signals based upon the one or more received signals.

Another example (e.g. example 31), relates to a previously-described example (e.g. example 30), wherein the processing means adjusts the phase shift of the set of adjustable phase shifters based on an amplitude of the one or more received signals.

Another example (e.g. example 32) relates to a previously-described example (e.g. one or more of examples 30-31), further comprising: a set of carrier signal generators configured, as part of a training process that generates signal training data, to selectively couple a respective one of the one or more received signals to different signal inputs of the communication device to generate different predetermined combinations of the one or more received signals.

Another example (e.g. example 33) relates to a previously-described example (e.g. one or more of examples 30-32), wherein the one or more received signals and the one or more output signals further comprise millimeter wave carrier frequencies.

Another example (e.g. example 34) relates to a previously-described example (e.g. one or more of examples 30-33), wherein the processing means generates the one or more output signals comprising predetermined output signal amplitudes based upon predetermined combinations of the one or more received signals.

Another example (e.g. example 35) relates to a previously-described example (e.g. one or more of examples 30-34), further comprising: a set of envelope detector means for measuring a respective amplitude of the one or more output signals, wherein the processing means determines, based upon the measured amplitude of the one or more output signals, whether a respective amplitude of the one or more output signals is within a threshold range.

Another example (e.g. example 36) relates to a previously-described example (e.g. one or more of examples 30-35), wherein: a computing matrix of the set of interconnected computing matrices comprises two hybrid couplers and two adjustable phase shifters, a first one of the two adjustable phase shifters is coupled to a first port of a first one of the two hybrid couplers, and a second one of the two adjustable phase shifters is coupled to a second port of the first one of the two hybrid couplers and to a first port of the second one of the two hybrid couplers.

Another example (e.g. example 37) relates to a previously-described example (e.g. one or more of examples 30-36), wherein the set of interconnected computing matrices comprise an interconnected set of lumped element hybrid couplers.

Another example (e.g. example 38) relates to a previously-described example (e.g. one or more of examples 30-37), wherein the CMOS IC further comprises transmission lines, and wherein the set of interconnected computing matrices are interconnected via the transmission lines.

An example (e.g. example 39) is directed to at least one non-transitory computer-readable medium comprising instructions stored thereon, that if executed by processing means, cause the processing means to: receive one or more input signals via an input means; output one or more output signals via an output means, wherein the input means and the output means are coupled to one another via a set of interconnected computing matrices included as part of a complementary metal oxide semiconductor (CMOS) integrated circuit (IC), and control a phase shift value of a set of adjustable phase shifters associated with the set of interconnected computing matrices to generate the one or more output signals based upon the one or more received signals.

Another example (e.g. example 40) relates to a previously-described example (e.g. example 39), wherein the instructions, if executed by the processing means, further cause the processing means to control the phase shift of the set of adjustable phase shifters based on an amplitude of the one or more received signals.

An example (e.g. example 41) is directed to a method, comprising: receiving one or more input signals via input circuitry; outputting one or more output signals via output circuitry; and coupling the input circuitry and the output circuitry to one another via a set of interconnected computing matrices, wherein each one of the set of interconnected computing matrices comprises a set of hybrid couplers and a set of adjustable phase shifters, providing, via each one of the set of adjustable phase shifters, an adjustable phase shift to generate the one or more output signals based upon the one or more input signals.

Another example (e.g. example 42) relates to a previously-described example (e.g. example 41), wherein the one or more input signals and the one or more output signals further comprise millimeter wave carrier frequencies.

Another example (e.g. example 43) relates to a previously-described example (e.g. one or more of examples 41-42), further comprising generating, via the set of interconnected computing matrices, the one or more output signals based on predetermined combinations of the one or more input signals.

Another example (e.g. example 44) relates to a previously-described example (e.g. one or more of examples 41-43), further comprising providing, via the set of adjustable phase shifters, the adjustable phase shift based at least on predetermined combinations of the one or more input signals as a function of phase shift value weights.

Another example (e.g. example 44) relates to a previously-described example (e.g. one or more of examples 41-43), further comprising measuring, via a set of envelope detectors included in the output circuitry, a respective amplitude of the one or more output signals; and determining, based on the measured respective amplitude, whether an amplitude of the one or more output signals is within a threshold range.

Another example (e.g. example 45) relates to a previously-described example (e.g. one or more of examples 41-44), further comprising a computing matrix of the set of interconnected computing matrices comprises two hybrid couplers and two adjustable phase shifters, a first one of the two adjustable phase shifters is coupled to a first port of a first one of the two hybrid couplers, and a second one of the two adjustable phase shifters is coupled to a second port of the first one of the two hybrid couplers and to a first port of the second one of the two hybrid couplers.

Another example (e.g. example 46) relates to a previously-described example (e.g. one or more of examples 41-45), wherein the set of hybrid couplers comprises one or more CMOS IC lumped element hybrid couplers.

Another example (e.g. example 47) relates to a previously-described example (e.g. one or more of examples 41-46), wherein the set of interconnected computing matrices are interconnected via CMOS IC transmission lines.

Another example (e.g. example 48) relates to a previously-described example (e.g. one or more of examples 41-47), wherein the input circuitry comprises a set of carrier frequency signal generators, and further comprising selectively coupling, via the set of carrier frequency signal generators, a respective one of the one or more input signals to the input circuitry to generate different input signal combinations.

An apparatus as shown and described.

A method as shown and described.

### CONCLUSION

The aforementioned description of the specific aspects will so fully reveal the general nature of the disclosure that others can, by applying knowledge within the skill of the art, readily modify and/or adapt for various applications such specific aspects, without undue experimentation, and without departing from the general concept of the present disclosure. Therefore, such adaptations and modifications are intended to be within the meaning and range of equivalents of the disclosed aspects, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

References in the specification to “one aspect,” “an aspect,” “an exemplary aspect,” etc., indicate that the aspect described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is submitted that it is within the knowledge of one skilled in the art to affect such feature, structure, or characteristic in connection with other aspects whether or not explicitly described.

The exemplary aspects described herein are provided for illustrative purposes, and are not limiting. Other exemplary aspects are possible, and modifications may be made to the exemplary aspects. Therefore, the specification is not meant to limit the disclosure. Rather, the scope of the disclosure is defined only in accordance with the following claims and their equivalents.

Aspects may be implemented in hardware (e.g., circuits), firmware, software, or any combination thereof. Aspects may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general purpose computer.

For the purposes of this discussion, the term “processing circuitry” or “processor circuitry” shall be understood to be circuit(s), processor(s), logic, or a combination thereof. For example, a circuit can include an analog circuit, a digital circuit, state machine logic, other structural electronic hardware, or a combination thereof. A processor can include a microprocessor, a digital signal processor (DSP), or other hardware processor. The processor can be “hard-coded” with instructions to perform corresponding function(s) according to aspects described herein. Alternatively, the processor can access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary aspects described herein, processing circuitry can include memory that stores data and/or instructions. The memory can be any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

What is claimed is:

1. An apparatus comprising:
input circuitry configured to receive one or more input signals;
output circuitry configured to output one or more output signals; and
a complementary metal oxide semiconductor (CMOS) integrated circuit (IC) comprising a set of interconnected computing matrices configured to couple the input circuitry and the output circuitry to one another,
wherein the set of interconnected computing matrices comprises a set of hybrid couplers and a set of adjustable phase shifters, the set of adjustable phase shifters configured to provide an adjustable phase shift to generate the one or more output signals.

2. The apparatus of claim 1, wherein the one or more input signals and the one or more output signals further comprise millimeter wave carrier frequencies.

3. The apparatus of claim 1, wherein the set of interconnected computing matrices are configured to generate the one or more output signals based on predetermined combinations of the one or more input signals.

4. The apparatus of claim 1, wherein the set of adjustable phase shifters is configured to provide the adjustable phase shift based at least on predetermined combinations of the one or more input signals as a function of phase shift value weights.

5. The apparatus of claim 1, wherein the output circuitry comprises a set of envelope detectors configured to measure a respective amplitude of the one or more output signals, and
wherein the measured respective amplitude is used to determine whether an amplitude of the one or more output signals is within a threshold range.

6. The apparatus of claim 1, wherein:
a computing matrix of the set of interconnected computing matrices comprises two hybrid couplers and two adjustable phase shifters,
a first one of the two adjustable phase shifters is coupled to a first port of a first one of the two hybrid couplers, and
a second one of the two adjustable phase shifters is coupled to a second port of the first one of the two hybrid couplers and to a first port of the second one of the two hybrid couplers.

7. The apparatus of claim 1, wherein the set of hybrid couplers comprises one or more CMOS IC lumped element hybrid couplers.

8. The apparatus of claim 1, wherein the set of interconnected computing matrices are interconnected via CMOS IC transmission lines.

9. The apparatus of claim 1, wherein the input circuitry comprises a set of carrier frequency signal generators configured to selectively couple a respective one of the one or more input signals to the input circuitry to generate different input signal combinations.

10. A communication device, comprising:
communication circuitry configured to receive one or more signals;
a complementary metal oxide semiconductor (CMOS) integrated circuit (IC) comprising a feedforward neural network (FNN) including a set of interconnected computing matrices configured to generate one or more output signals based upon the one or more received signals; and
processing circuitry configured to control a phase shift of a set of adjustable phase shifters associated with the set of interconnected computing matrices to generate the one or more output signals based upon the one or more received signals.

11. The communication device of claim 10, wherein the processing circuitry is configured to adjust the phase shift of the set of adjustable phase shifters based on an amplitude of the one or more received signals.

12. The communication device of claim 10, further comprising:
a set of carrier signal generators configured, as part of a training process that generates signal training data, to selectively couple a respective one of the one or more received signals to different signal inputs of the communication device to generate different predetermined combinations of the one or more received signals.

13. The communication device of claim 10, wherein the one or more received signals and the one or more output signals further comprise millimeter wave carrier frequencies.

14. The communication device of claim 10, wherein the processing circuitry is configured to generate the one or more output signals comprising predetermined output signal amplitudes based upon predetermined combinations of the one or more received signals.

15. The communication device of claim 10, further comprising:
a set of envelope detectors configured to measure a respective amplitude of the one or more output signals,
wherein the processing circuitry is configured to determine, based upon the measured amplitude of the one or more output signals, whether a respective amplitude of the one or more output signals is within a threshold range.

16. The communication device of claim 10, wherein:
a computing matrix of the set of interconnected computing matrices comprises two hybrid couplers and two adjustable phase shifters,
a first one of the two adjustable phase shifters is coupled to a first port of a first one of the two hybrid couplers, and
a second one of the two adjustable phase shifters is coupled to a second port of the first one of the two hybrid couplers and to a first port of the second one of the two hybrid couplers.

17. The communication device of claim 10, wherein the set of interconnected computing matrices comprise an interconnected set of lumped element hybrid couplers.

18. The communication device of claim 10, wherein the CMOS IC further comprises transmission lines, and
wherein the set of interconnected computing matrices are interconnected via the transmission lines.

19. At least one non-transitory computer-readable medium comprising instructions stored thereon, that if executed by one or more processors, cause the one or more processors to:
receive one or more input signals via input circuitry;
output one or more output signals via output circuitry,
wherein the input circuitry and the output circuitry are coupled to one another via a set of interconnected computing matrices included as part of a complementary metal oxide semiconductor (CMOS) integrated circuit (IC), and
control a phase shift value of a set of adjustable phase shifters associated with the set of interconnected computing matrices to generate the one or more output signals based upon the one or more received signals.

20. The non-transitory computer-readable medium of claim 19, wherein the instructions, if executed by one or more processors, further cause the one or more processors to control the phase shift of the set of adjustable phase shifters based on an amplitude of the one or more received signals.
